(19) United States
(12) Patent Application Publication
(10) Pub. No.: US 2022/0359563 A1
(43) Pub. Date: Nov. 10, 2022

(54) THREE-DIMENSIONAL SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Youngji Noh, Suwon-si (KR); Jung-Hwan Park, Seongnam-si (KR); Kwangyoung Jung, Hwaseong-si (KR); Hyojoon Ryu, Hwaseong-si (KR); Jeehoon Han, Hwaseong-si (KR)

(21) Appl. No.: 17/651,633

(22) Filed: Feb. 18, 2022

(30) Foreign Application Priority Data
May 6, 2021 (KR) 10-2021-0058682

(51) Int. Cl. H01L 27/11582; H01L 27/11556; H01L 27/11519; H01L 27/11524; H01L 27/11526; H01L 27/11565; H01L 27/1157; H01L 27/11573; H01L 23/528

(52) U.S. Cl. CPC H01L 27/11582; H01L 27/11556; H01L 27/11519; H01L 27/11524; H01L 27/11526; H01L 27/11565; H01L 27/1157; H01L 27/11573; H01L 23/5283

(57) ABSTRACT

Provided are three-dimensional semiconductor memory devices and electronic systems including the same. The device includes a substrate, stack structures each including interlayer dielectric layers and gate electrodes, which are alternately and repeatedly stacked on the substrate, vertical channel structures which penetrate the stack structures, and a separation structure, which extends in a first direction across between the stack structures. The separation structure includes first parts each having a pillar shape, which extend in a third direction perpendicular to a top surface of the substrate, and second parts, which extend between the interlayer dielectric layers from sidewalls of the first parts and which connect the first parts to each other in the first direction. The separation structure is spaced apart from the vertical channel structures in a second direction which intersects the first direction.

### CROSS-REFERENCE TO RELATED APPLICATION

This U.S. nonprovisional application claims priority under 35 U.S.C § 119 to Korean Patent Application No. 10-2021-0058682 filed on May 6, 2021 in the Korean Intellectual Property Office, the disclosure of which is hereby incorporated by reference in its entirety.

### BACKGROUND

Embodiments of the present inventive concept relate to a three-dimensional semiconductor memory device and an electronic system including the same, and more particularly, to a nonvolatile three-dimensional semiconductor memory device including a vertical channel structure, a method of fabricating the same, and an electronic system including the same.

A semiconductor device capable of storing a large amount of data may be used in an electronic system, which requires data storage. Semiconductor devices have been highly integrated to meet high performance and low manufacturing cost goals, which may be desired by customers. Integration of typical two-dimensional or planar semiconductor devices is primarily determined by the area occupied by a unit memory cell, such that it may be greatly influenced by the level of technology for forming fine patterns. However, the processing equipment used to increase pattern fineness may be expensive and may set a practical limitation on increasing the integration the two-dimensional or planar semiconductor devices. Therefore, three-dimensional semiconductor memory devices having three-dimensionally arranged memory cells have been proposed for increasing the integration density.

### SUMMARY

Some embodiments of the present inventive concepts may provide a three-dimensional semiconductor memory device whose reliability and electric characteristics are improved and a simplified method of fabricating the same.

Some embodiments of the present inventive concepts may provide an electronic system including the three-dimensional semiconductor memory device.

Embodiments of the present inventive concepts are not limited to those mentioned above, and other embodiments of the inventive concept will be clearly understood to those skilled in the art from the following description.

According to some embodiments of the present inventive concepts, a three-dimensional semiconductor memory device may comprise: a substrate; a plurality of stack structures each including a plurality of interlayer dielectric layers and a plurality of gate electrodes, which are alternately and repeatedly stacked on the substrate; a plurality of vertical channel structures, which penetrates the plurality of stack structures; and a separation structure which extends in a first direction across between the plurality of stack structures. The separation structure may include: a plurality of first parts each having a pillar shape, which extends in a third direction perpendicular to a top surface of the substrate; and a plurality of second parts, which extends between the plurality of interlayer dielectric layers from sidewalls of the plurality of first parts and which connects one of the plurality of first parts to each other in the first direction. The separation structure may be spaced apart in a second direction from the plurality of vertical channel structures. The second direction may intersect the first direction.

According to some embodiments of the present inventive concepts, a three-dimensional semiconductor memory device may comprise: a first substrate including a cell array region and a contact region, which is adjacent in a first direction to the cell array region; a peripheral circuit structure including a plurality of peripheral transistors on the first substrate; a second substrate on the peripheral circuit structure, the second substrate extending from the cell array region toward the contact region; a plurality of stack structures including a plurality of interlayer dielectric layers and a plurality of gate electrodes, which are alternately and repeatedly stacked on the second substrate; a source structure between the second substrate and the plurality of stack structures; a planarized dielectric layer on the plurality of stack structures; a plurality of vertical channel structures, which penetrates the planarized dielectric layer, the plurality of stack structures, and the source structure and which are in physical contact with the second substrate; an upper dielectric layer on top surfaces of the plurality of stack structures, a top surface of the planarized dielectric layer, and top surfaces of the plurality of vertical channel structures; a plurality of cell contact plugs on the contact region, the cell contact plugs penetrating the upper dielectric layer and the planarized dielectric layer, the cell contact plugs being in physical contact with the plurality of gate electrodes of the plurality of stack structures; and a separation structure which extends in the first direction across the plurality of stack structures. The separation structure may include: a plurality of first parts each having a pillar shape which vertically extends from the second substrate; and a plurality of second parts, which extends between the plurality of interlayer dielectric layers from sidewalls of the plurality of first parts and which connects ones of the plurality of first parts to each other in the first direction. A sidewall of each of the second parts may have a profile shaped like an embossed line which extends in the first direction.

According to some embodiments of the present inventive concepts, an electronic system may comprise: a three-dimensional semiconductor memory device including a substrate, a plurality of stack structures including a plurality of interlayer dielectric layers and a plurality of gate electrodes, which are alternately and repeatedly stacked on the substrate, a plurality of vertical channel structures, which penetrates the plurality of stack structures, a separation structure which extends in a first direction across the plurality of stack structures, an upper dielectric layer, which is on top surfaces of the plurality of stack structures and top surfaces of the plurality of vertical channel structures, and an input/output pad on the upper dielectric layer; and a controller, which has an electrical connection through the input/output pad with the three-dimensional semiconductor memory device and which is configured to control the three-dimensional semiconductor memory device. The separation structure may include: a plurality of first parts each having a pillar shape, which extends in a third direction perpendicular to a top surface of the substrate; and a plurality of second parts, which extends between the plurality of interlayer dielectric layers from sidewalls of the plurality of first parts and which connects ones of the plurality of first parts to each other in the first direction. The separation structure may be spaced apart in a second direction from the plurality of vertical channel structures. The second direction may intersect the first direction.

### BRIEF DESCRIPTION OF THE DRAWINGS

FIG. 1 illustrates a simplified block diagram illustrating an electronic system that includes a three-dimensional semiconductor memory device according to some embodiments of the present inventive concepts.

FIG. 2 illustrates a simplified perspective view illustrating an electronic system that includes a three-dimensional semiconductor memory device according to some embodiments of the present inventive concepts.

FIGS. 3 and 4 illustrate cross-sectional views respectively taken along lines I-I′ and II-II′ of FIG. 2, illustrating a semiconductor package that includes a three-dimensional semiconductor memory device according to some embodiments of the present inventive concepts.

FIG. 5A illustrates a plan view illustrating a three-dimensional semiconductor memory device according to some embodiments of the present inventive concepts.

FIGS. 5B, 5C, and 5D illustrate cross-sectional views respectively taken along lines I-I′, II-II′, and III-III′ of FIG. 5A, illustrating a three-dimensional semiconductor memory device according to some embodiments of the present inventive concepts.

FIGS. 6 and 7 illustrate enlarged cross-sectional views of section A depicted in FIG. 5A, partially illustrating a three-dimensional semiconductor memory device according to some embodiments of the present inventive concepts.

FIG. 8 illustrates an enlarged view of section B depicted in FIG. 5B, partially illustrating a three-dimensional semiconductor memory device according to some embodiments of the present inventive concepts.

FIGS. 9A, 10A, 11A, and 12A illustrate plan views illustrating a method of fabricating a three-dimensional semiconductor memory device according to some embodiments of the present inventive concepts.

FIGS. 9B, 9C, 10B to 10D, 11B to 11D, 12B, and 12C illustrate cross-sectional views taken along lines I-I′, II-II′, and III-III′ of FIGS. 9A, 10A, 11A, and 12A, illustrating a method of fabricating a three-dimensional semiconductor memory device according to some embodiments of the present inventive concepts.

FIG. 13 illustrates a cross-sectional view taken along line II-II′ of FIG. 5A, illustrating a three-dimensional semiconductor memory device according to some embodiments of the present inventive concepts.

FIG. 14 illustrates a plan view illustrating a three-dimensional semiconductor memory device according to some embodiments of the present inventive concepts.

### DETAILED DESCRIPTION OF EMBODIMENTS

With reference to the accompanying drawings, the following will now describe in detail a three-dimensional semiconductor memory device, a method of fabricating the same, and an electronic system including the same according to some embodiments of the present inventive concepts. It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

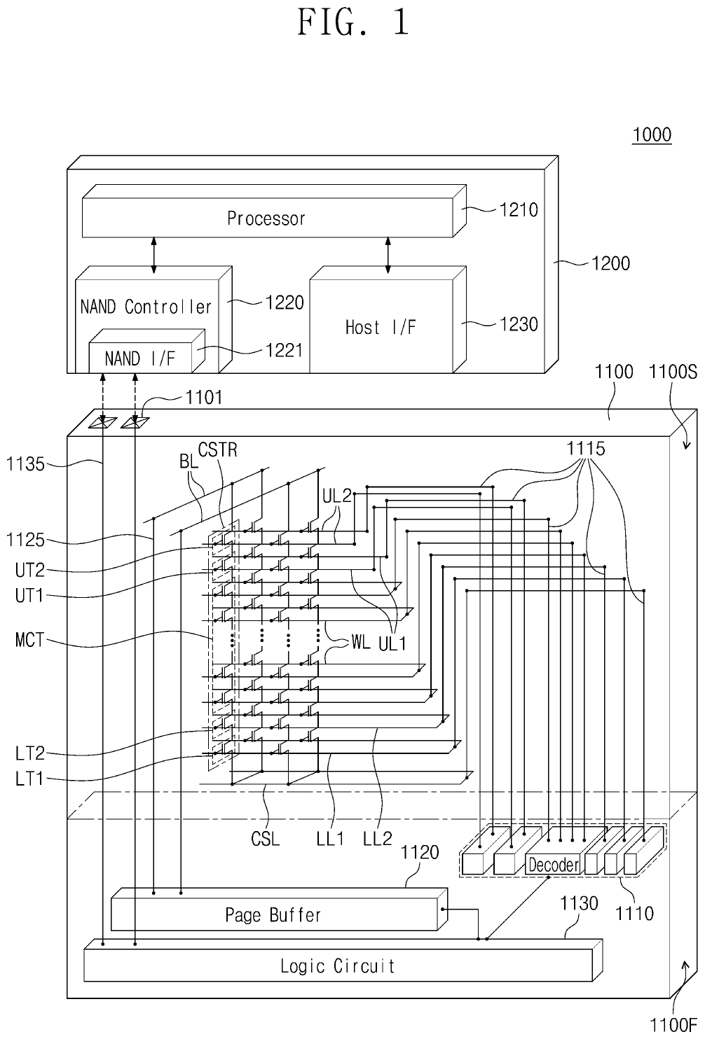

FIG. 1 illustrates a simplified block diagram illustrating an electronic system that includes a three-dimensional semiconductor memory device according to some embodiments of the present inventive concepts.

Referring to FIG. 1, an electronic system 1000 according to some embodiments of the present inventive concepts may include a three-dimensional semiconductor memory device 1100 and a controller 1200 electrically connected to the three-dimensional semiconductor memory device 1100. The electronic system 1000 may be a storage device that includes one or more three-dimensional semiconductor memory devices 1100 or may be an electronic device that includes the storage device. For example, the electronic system 1000 may be a solid state drive (SSD) device, a universal serial bus (USB), a computing system, a medical apparatus, or a communication apparatus each of which includes one or more three-dimensional semiconductor memory devices 1100.

The three-dimensional semiconductor memory device 1100 may be a nonvolatile memory device, such as a three-dimensional NAND Flash memory device, which will be described below. The three-dimensional semiconductor memory device 1100 may include a first region 1100F and a second region 1100S on the first region 1100F. For example, the first region 1100F may be disposed on a side of the second region 1100S. The first region 1100F may be a peripheral circuit region that includes a decoder circuit 1110, a page buffer 1120, and a logic circuit 1130. The second region 11005 may be a memory cell region that includes bit lines BL, a common source line CSL, word lines WL, first lines LL1 and LL2, second lines UL1 and UL2, and memory cell strings CSTR between the bit line BL and the common source line CSL.

On the second region 11005, each of the memory cell strings CSTR may include first transistors LT1 and LT2 adjacent to the common source line CSL, second transistors UT1 and UT2 adjacent to the bit line BL, and memory cell transistors MCT disposed between the first transistors LT1 and LT2 and the second transistors UT1 and UT2. The number of the first transistors LT1 and LT2 and of the second transistors UT1 and UT2 may be variously changed in accordance with different embodiments of the inventive concept.

For example, the first transistors LT1 and LT2 may include a ground selection transistor, and the second transistors UT1 and UT2 may include a string selection transistor. The first lines LL1 and LL2 may be gate electrodes of the first transistors LT1 and LT2, respectively. The word lines WL may be gate electrodes of the memory cell transistors MCT. The second lines UL1 and UL2 may be gate electrodes of the second transistors UT1 and UT2, respectively.

For example, the first transistors LT1 and LT2 may include a first erasure control transistor LT1 and a ground selection transistor LT2 that are connected in series. The second transistors UT1 and UT2 may include a string selection transistor UT1 and a second erasure control transistor UT2 that are connected in series. One or both of the first and second erasure control transistors LT1 and UT2 may be used to perform an erase operation in which a gate induced drain leakage (GIDL) phenomenon is used to erase data stored in the memory cell transistors MCT.

The common source line CSL, the first lines LL1 and LL2, the word lines WL, and the second lines UL1 and UL2 may be electrically connected to the decoder circuit 1110 through first connection lines 1115 that extend from the first region 1100F toward the second region 1100S. The bit lines BL may be electrically connected to the page buffer 1120 through second connection lines 1125 that extend from the first region 1100F toward the second region 1100S.

On the first region 1100F, the decoder circuit 1110 and the page buffer 1120 may be configured to perform a control operation for at least one selection memory cell transistor among the plurality of memory cell transistors MCT. The logic circuit 1130 may be configured to control the decoder circuit 1110 and the page buffer 1120. The three-dimensional semiconductor memory device 1100 may be configured to communicate with the controller 1200 through an input/output pad 1101 electrically connected to the logic circuit 1130. The input/output pad 1101 may be electrically connected to the logic circuit 1130 through an input/output connection line 1135 that extends from the first region 1100F toward the second region 1100S.

The controller 1200 may include a processor 1210, a NAND controller 1220, and a host interface 1230. For example, the electronic system 1000 may include a plurality of three-dimensional semiconductor memory devices 1100, and in this case, the controller 1200 may be configured to control the plurality of three-dimensional semiconductor memory devices 1100.

The processor 1210 may be configured to control an overall operation of the electronic system 1000 that includes the controller 1200. The processor 1210 may be configured to operate based on certain firmware, and may be configured to control the NAND controller 1220 to access the three-dimensional semiconductor memory device 1100. The NAND controller 1220 may include NAND interface 1221 that is configured to process communication with the three-dimensional semiconductor memory device 1100. The NAND interface 1221 may be used to transfer therethrough a control command, which is intended to control the three-dimensional semiconductor memory device 1100, data which is intended to be written on the memory cell transistors MCT of the three-dimensional semiconductor memory device 1100, and/or data, which is intended to be read from the memory cell transistors MCT of the three-dimensional semiconductor memory device 1100. The host interface 1230 may be configured to provide the electronic system 1000 with communication with an external host. When a control command is received through the host interface 1230 from an external host, the three-dimensional semiconductor memory device 1100 may be controlled by the processor 1210 in response to the control command.

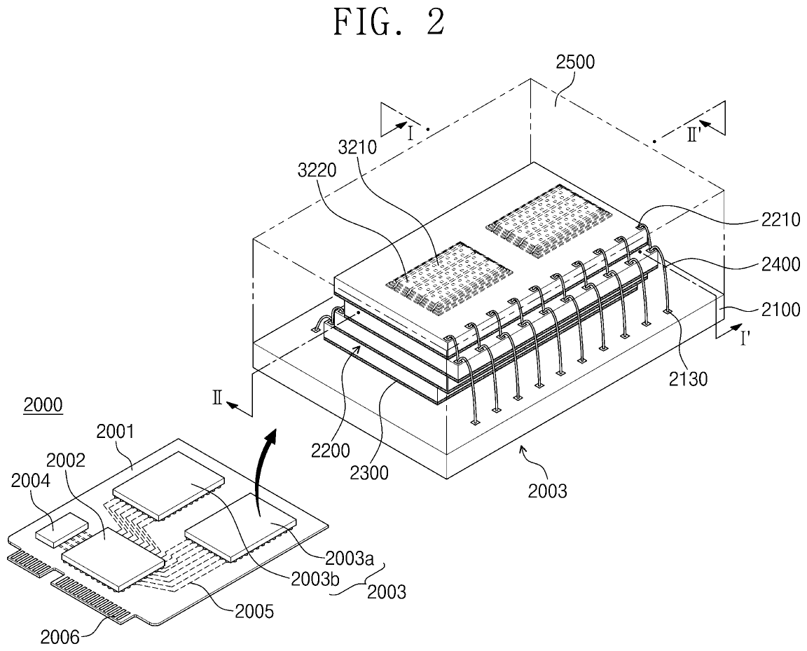

FIG. 2 illustrates a simplified perspective view showing an electronic system that includes a three-dimensional semiconductor memory device according to some embodiments of the present inventive concepts.

Referring to FIG. 2, an electronic system 2000 according to some embodiments of the present inventive concepts may include a main board 2001, a controller 2002 mounted on the main board 2001, one or more semiconductor packages 2003, and a dynamic random access memory (DRAM) 2004. The semiconductor package 2003 and the DRAM 2004 may be connected to the controller 2002 through wiring patterns 2005 provided in the main board 2001.

The main board 2001 may include a connector 2006 including a plurality of pins that are provided to have connection with an external host. The number and arrangement of the plurality of pins on the connector 2006 may be changed based on a communication interface between the electronic system 2000 and the external host. The electronic system 2000 may communicate with the external host through one or more interfaces, for example, universal serial bus (USB), peripheral component interconnect express (PIC-Express), serial advanced technology attachment (SATA), and/or M-PHY for universal flash storage (UFS). For example, the electronic system 2000 may operate with power supplied through the connector 2006 from the external host. The electronic system 2000 may further include a power management integrated circuit (PMIC) by which the power supplied from the external host is distributed to the controller 2002 and the semiconductor package 2003.

The controller 2002 may be configured to write data to the semiconductor package 2003, may be configured to read data from the semiconductor package 2003, or may be configured to increase an operating speed of the electronic system 2000.

The DRAM 2004 may be a buffer memory that is configured to reduce a difference in speed between an external host and the semiconductor package 2003 that serves as a data storage space. The DRAM 2004 included in the electronic system 2000 may be configured to operate as a cache memory, and may provide a space for temporary data storage in a control operation of the semiconductor package 2003. When the DRAM 2004 is included in the electronic system 2000, the controller 2002 may include not only an NAND controller for controlling the semiconductor package 2003, but a DRAM controller for controlling the DRAM 2004.

The semiconductor package 2003 may include first and second semiconductor packages 2003a and 2003b that are spaced apart from each other. Each of the first and second semiconductor packages 2003a and 2003b may include a plurality of semiconductor chips 2200. Each of the first and second semiconductor package 2003a and 2003b may include a package substrate 2100, semiconductor chips 2200 on the package substrate 2100, adhesive layers 2300 on bottom surfaces of the semiconductor chips 2200, connection structures 2400 that electrically connect the semiconductor chips 2200 to the package substrate 2100, and a molding layer 2500 that lies on the package substrate 2100 and is on and at least partially covers the semiconductor chips 2200 and the connection structures 2400.

The package substrate 2100 may be an integrated circuit board including package upper pads 2130. Each of the semiconductor chips 2200 may include input/output pads 2210. Each of the input/output pads 2210 may correspond to the input/output pad 1101 of FIG. 1. Each of the semiconductor chips 2200 may include gate stack structures 3210 and vertical channel structures 3220. Each of the semiconductor chips 2200 may include a three-dimensional semiconductor memory device, which will be described below.

For example, the connection structures 2400 may be bonding wires that electrically connect the input/output pads 2210 to the package upper pads 2130. On each of the first and second semiconductor packages 2003a and 2003b , the semiconductor chips 2200 may be electrically connected to each other in a wire bonding manner, and may be electrically connected to the package upper pads 2130 of the package substrate 2100. In some embodiments, on each of the first and second semiconductor packages 2003a and 2003b , the semiconductor chips 2200 may be electrically connected to each other using through-silicon vias (TSVs) instead of the connection structures 2400 or the bonding wires.

For example, the controller 2002 and the semiconductor chips 2200 may be included in a single package. For example, the controller 2002 and the semiconductor chips 2200 may be mounted on a separate interposer substrate other than the main board 2001, and may be connected to each other through lines provided in the interposer substrate.

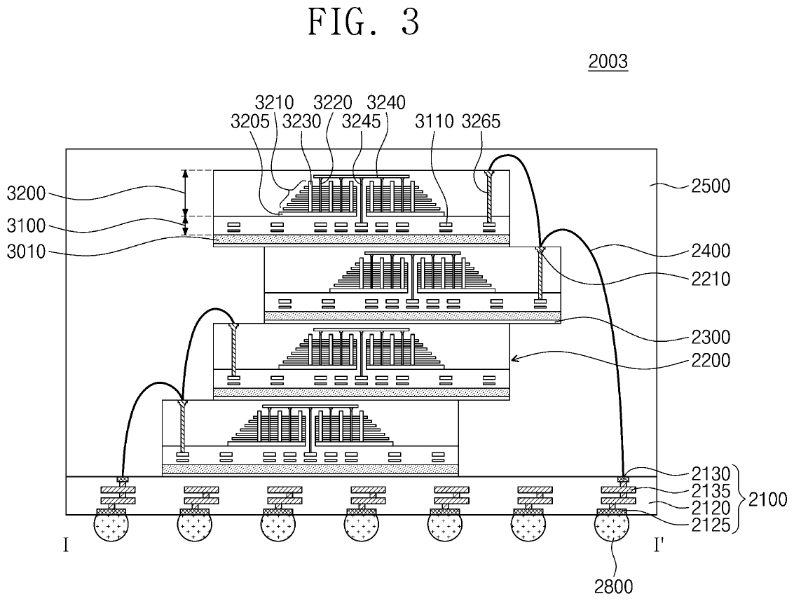

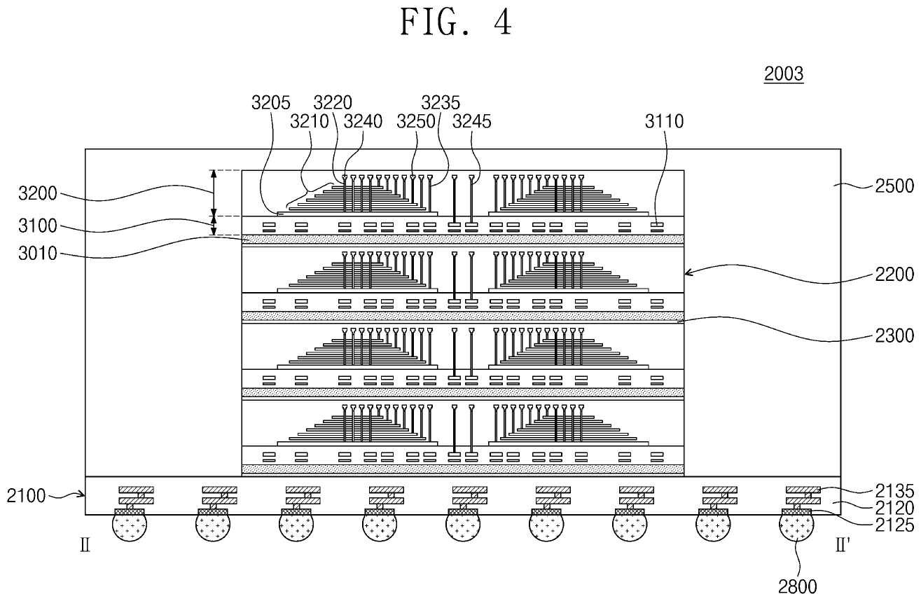

FIGS. 3 and 4 are cross-sectional views respectively taken along lines I-I′ and II-II′ of FIG. 2, which illustrate a semiconductor package that includes a three-dimensional semiconductor memory device according to some embodiments of the present inventive concepts.

Referring to FIGS. 3 and 4, a semiconductor package 2003 may include a package substrate 2100, a plurality of semiconductor chips on the package substrate 2100, and a molding layer 2500 that is on at least partially covers the package substrate 2100 and the plurality of semiconductor chips.

The package substrate 2100 may include a package substrate body 2120, package upper pads 2130 disposed on a top surface of the package substrate body 2120, package lower pads 2125 disposed or exposed on a bottom surface of the package substrate body 2120, and internal lines 2135 that lie in the package substrate body 2120 and electrically connect the package upper pads 2130 to the package lower pads 2125. The package upper pads 2130 may be electrically connected to connection structures 2400. The package lower pads 2125 may be connected through conductive connectors 2800 to the wiring patterns 2005 in the main board 2001 of the electronic system 2000 depicted in FIG. 2.

Each of the semiconductor chips 2200 may include a semiconductor substrate 3010, and may also include a first structure 3100 and a second structure 3200 that are sequentially stacked on the semiconductor substrate 3010. The first structure 3100 may include a peripheral circuit region including peripheral lines 3110. The second structure 3200 may include a common source line 3205, a gate stack structure 3210 on the common source line 3205, vertical channel structures 3220 and separation structure 3230 that penetrate the gate stack structure 3210, bit lines 3240 electrically connected to the vertical channel structures 3220, gate connection lines 3235 and conductive lines 3250 that are electrically connected to word lines (see WL of FIG. 1) of the gate stack structure 3210.

Each of the semiconductor chips 2200 may include one or more through lines 3245 that have an electrical connection with the peripheral lines 3110 of the first structure 3100 and extend into the second structure 3200. The through line 3245 may penetrate the gate stack structure 3210, and may further be disposed outside the gate stack structure 3210. Each of the semiconductor chips 2200 may further include an input/output connection line 3265 that has an electrical connection with the peripheral line 3110 of the first structure 3100 and extends into the second structure 3200, and may also further include an input/output pad 2210 electrically connected to the input/output connection line 3265.

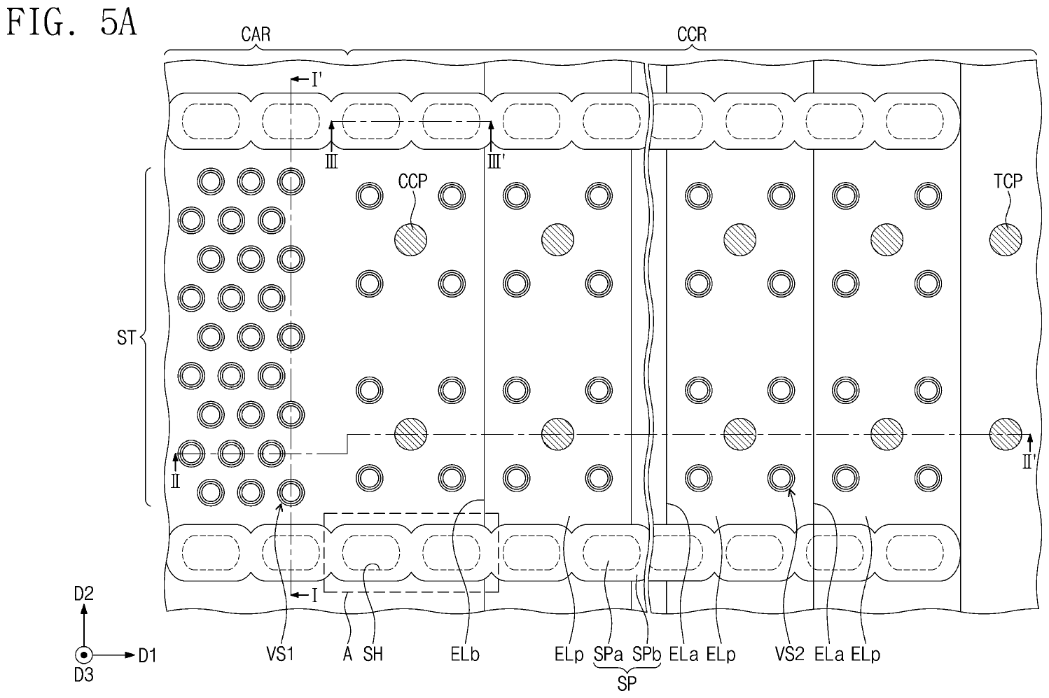

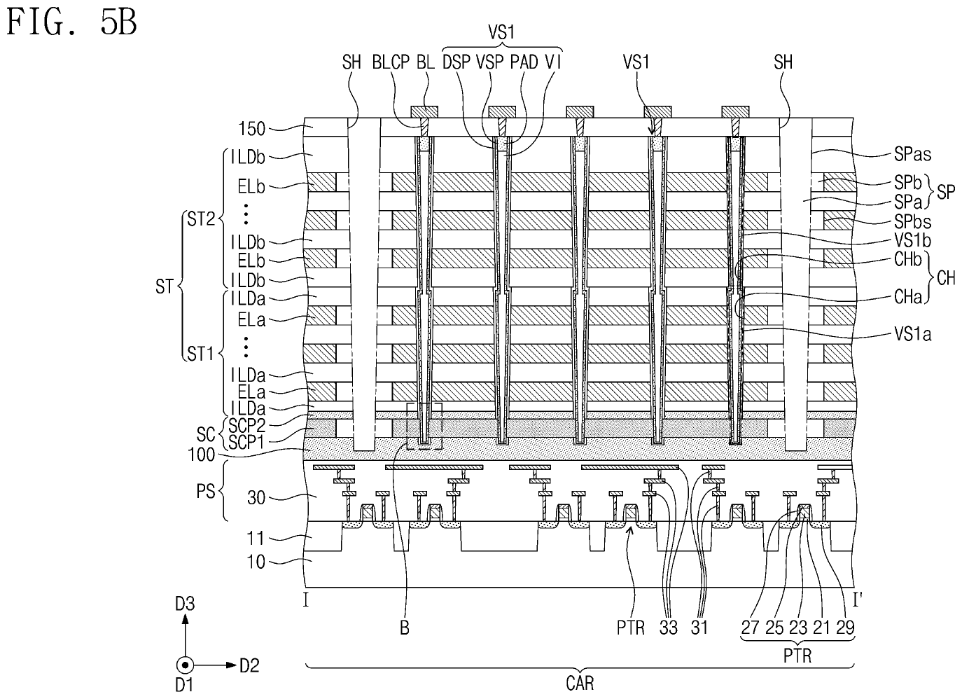

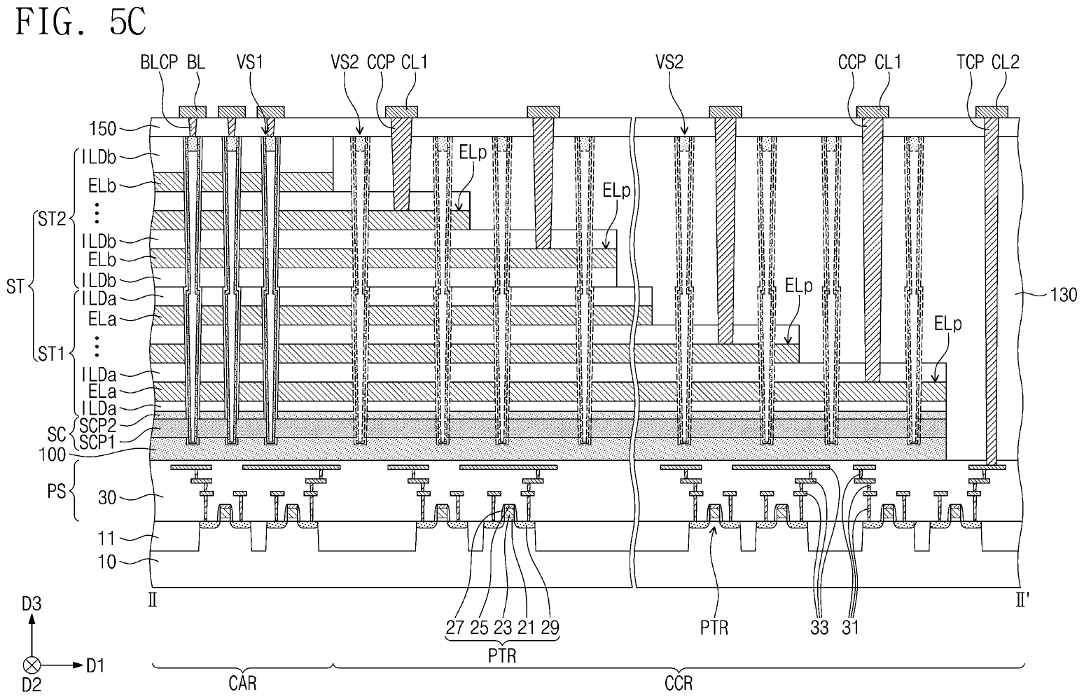

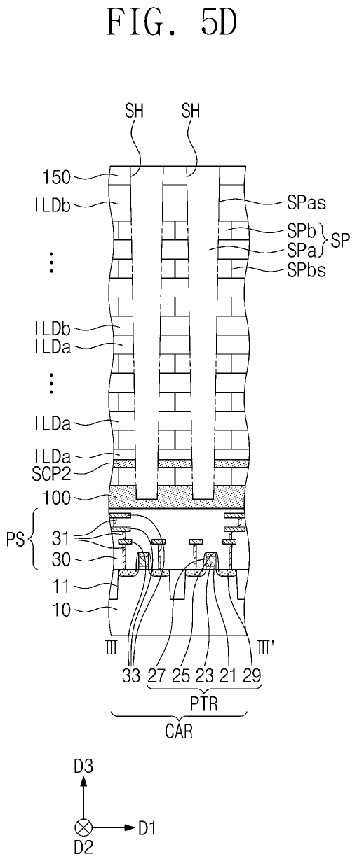

FIG. 5A illustrates a plan view illustrating a three-dimensional semiconductor memory device according to some embodiments of the present inventive concepts. FIGS. 5B, 5C, and 5D are cross-sectional views respectively taken along lines I-I′, II-II′, and III-III′ of FIG. 5A, illustrating a three-dimensional semiconductor memory device according to some embodiments of the present inventive concepts.

Referring to FIGS. 5A, 5B, 5C, and 5D, a first substrate 10 may be provided to include a cell array region CAR and a contact region CCR. The first substrate 10 may extend in a first direction D1 from the cell array region CAR toward the contact region CCR and in a second direction D2 that intersects the first direction D1. The first substrate 10 may have a top surface perpendicular to a third direction D3 that intersects the first and second directions D1 and D2. For example, the first, second, and third directions D1, D2, and D3 may be orthogonal to each other.

When viewed in plan, the contact region CCR may extend in the first direction D1 (or a direction opposite to the first direction D1) from the cell array region CAR. The cell array region CAR may be a zone on which are provided the vertical channel structure 3220, the separation structures 3230, and the bit lines 3240 electrically connected to the vertical channel structures 3220, which components 3220, 3230, and 3240 are described with reference to FIGS. 3 and 4. The contact region CCR may be a zone on which is provided a stepwise structure including pad portions ELp, which will be described below. Differently from that shown, the contact region CCR may extend in the second direction D2 (or a direction opposite to the second direction D2) from the cell array region CAR.

The first substrate 10 may be, for example, a silicon substrate, a silicon-germanium substrate, a germanium substrate, and/or a monocrystalline epitaxial layer grown on a monocrystalline silicon substrate. A device isolation layer 11 may be provided in the first substrate 10. The device isolation layer 11 may define an active area of the first substrate 10. The device isolation layer 11 may include, for example, silicon oxide.

A peripheral circuit structure PS may be provided on the first substrate 10. The peripheral circuit structure PS may include peripheral transistors PTR on the active area of the first substrate 10, peripheral circuit plugs 31, peripheral circuit lines 33 electrically connected through the peripheral circuit plugs 31 to the peripheral transistors PTR, and a peripheral circuit dielectric layer 30 that borders or surrounds the peripheral transistors PTR, the peripheral circuit plugs 31, and the peripheral circuit lines 33. The peripheral structure PS may correspond to the first region 1100F of FIG. 1, and the peripheral circuit lines 33 may correspond to the peripheral lines 3110 of FIGS. 3 and 4.

A peripheral circuit may be constituted by the peripheral transistors PTR, the peripheral circuit plugs 31, and the peripheral circuit lines 33. For example, the peripheral transistors PTR may constitute the decoder circuit 1110, the page buffer 1120, and the logic circuit 1130 of FIG. 1. For example, each of the peripheral transistors PTR may include a peripheral gate dielectric layer 21, a peripheral gate electrode 23, a peripheral capping pattern 25, a peripheral gate spacer 27, and peripheral source/drain sections 29.

The peripheral gate dielectric layer 21 may be provided between the peripheral gate electrode 23 and the first substrate 10. The peripheral capping pattern 25 may be provided on the peripheral gate electrode 23. The peripheral gate spacer 27 may be on and at least partially cover sidewalls of the peripheral gate dielectric layer 21, the peripheral gate electrode 23, and the peripheral capping pattern 25. The peripheral source/drain sections 29 may be provided in the first substrate 10 adjacent to opposite sides of the peripheral gate electrode 23.

The peripheral circuit lines 33 may be electrically connected through the peripheral circuit plugs 31 to the peripheral transistors PTR. Each of the peripheral transistors PTR may be, for example, an NMOS transistor, a PMOS transistor, or a gate-all-around type transistor. For example, the peripheral circuit plugs 31 may have a width in the first direction D1 or the second direction D2, and the width may increase with increasing distance from the first substrate 10. The peripheral circuit plugs 31 and the peripheral circuit lines 33 may include a conductive material, such as metal.

The peripheral circuit dielectric layer 30 may be provided on the top surface of the first substrate 10. On the first substrate 10, the peripheral circuit dielectric layer 30 may be on and at least partially cover the peripheral transistors PTR, the peripheral circuit plugs 31, and the peripheral circuit lines 33. The peripheral circuit dielectric layer 30 may include a plurality of dielectric layers that constitute a multi-layered structure. For example, the peripheral circuit dielectric layer 30 may include one or more of silicon oxide, silicon nitride, silicon oxynitride, and low-k dielectric materials.

A second substrate 100 may be provided on the peripheral circuit dielectric layer 30. The second substrate 100 may extend in the first and second directions D1 and D2. The second substrate 100 may not be provided on a portion of the contact region CCR. The second substrate 100 may be a semiconductor substrate including a semiconductor material. The second substrate 100 may include, for example, silicon (Si), germanium (Ge), silicon germanium (SiGe), gallium arsenic (GaAs), indium gallium arsenic (InGaAs), aluminum gallium arsenic (AlGaAs), or a mixture thereof.

A stack structure ST may be provided on the second substrate 100. The stack structure ST may extend from the cell array region CAR toward the contact region CCR. The stack structure ST may correspond to the stack structure 3210 of FIG. 3 or 4. The stack structure ST may be provided in plural, and the plurality of stack structures ST may be arranged along the second direction D2 and may be spaced apart from each other in the second direction D2 across a separation structure SP, which will be described below. For convenience of description, the following explanation will focus on a single stack structure ST, but this explanation may also be applicable to other stack structures ST.

The stack structure ST may include interlayer dielectric layers ILDa and ILDb and gate electrodes ELa and ELb that are alternately and repeatedly stacked. The gate electrodes ELa and ELb may correspond to the word lines WL, the first lines LL1 and LL2, and the second lines UL1 and UL2 of FIG. 1.

The stack structure ST may include, for example, a first stack structure ST1 on the second substrate 100 and a second stack structure ST2 on the first stack structure ST1. The first stack structure ST1 may include first interlayer dielectric layers ILDa and first gate electrodes ELa that are alternately and repeatedly stacked, and the second stack structure ST2 may include second interlayer dielectric layers ILDb and second gate electrodes ELb that are alternately and repeatedly stacked. The first and second gate electrodes ELa and ELb may have substantially the same thickness in the third direction D3. In the description below, the term “thickness” may indicate a thickness in the third direction D3.

The first and second gate electrodes ELa and ELb may have lengths in the first direction D1 that decrease with increasing distance (or in the third direction D3) from the second substrate 100. For example, each of the first and second gate electrodes ELa and ELb may have a length in the first direction D1 that is greater than a length in the first direction D1 of a next overlying gate electrode. A lowermost one of the first gate electrodes ELa included in the first stack structure ST1 may have the longest length in the first direction D1, and an uppermost one of the second gate electrodes ELb included in the second stack structure ST2 may have the shortest length in the first direction D1.

The first and second gate electrodes ELa and ELb may have their pad portions ELp on the contact region CCR. The pad portions ELp of the first and second gate electrodes ELa and ELb may be disposed at their positions that are horizontally and vertically different from each other. The pad portions ELp may constitute a stepwise structure along the first direction D1.

The stepwise structure may be arranged such that each of the first and second stack structures ST1 and ST2 may have a thickness which decreases with increasing distance from an outermost one of first vertical channel structures VS1, which will be described below, and that the first and second gate electrodes ELa and ELb may have their sidewalls spaced apart from each other along the first direction D1 at a regular interval when viewed in plan.

The first and second gate electrodes ELa and ELb may include, for example, at least one material selected from doped semiconductors (e.g., doped silicon), metals (e.g., tungsten, copper, or aluminum), conductive metal nitrides (e.g., titanium nitride, or tantalum nitride), and transition metals (e.g., titanium or tantalum).

The first and second interlayer dielectric layers ILDa and ILDb may be provided between the first and second gate electrodes ELa and ELb, and may each have a sidewall aligned with that of an underlying one of the first and second gate electrodes ELa and ELb. For example, likewise the first and second gate electrodes ELa and ELb, the first and second interlayer dielectric layers ILDa and ILDb may have their lengths in the first direction D1 that decrease with increasing distance from the second substrate 100.

A lowermost one of the second interlayer dielectric layers ILDb may be in physical contact with an uppermost one of the first interlayer dielectric layers ILDa. For example, each of the first and second interlayer dielectric layers ILDa and ILDb may have a thickness less than that of each of the first and second gate electrodes ELa and ELb. For example, a lowermost one of the first interlayer dielectric layers ILDa may have a thickness less than that of each of other interlayer dielectric layers ILDa and ILDb. For example, uppermost and lowermost ones of the second interlayer dielectric layers ILDb may have respective thicknesses greater than that of each of the other interlayer dielectric layers ILDa and ILDb.

Except for the lowermost one of the first interlayer dielectric layers ILDa, the uppermost one of the second interlayer dielectric layers ILDb, and the lowermost one of the second interlayer dielectric layers ILDb, other interlayer dielectric layers ILDa and ILDb may have substantially the same thickness. This, however, is merely an example, and the first and second interlayer dielectric layers ILDa and ILDb may have thicknesses that vary based on properties of a semiconductor device.

The first and second interlayer dielectric layers ILDa and ILDb may include, for example, one or more of silicon oxide, silicon nitride, silicon oxynitride, and low-k dielectric materials. For example, the first and second interlayer dielectric layers ILDa and ILDb may include high-density plasma (HDP) oxide or tetraethylorthosilicate (TEOS).

A source structure SC may be provided between the second substrate 100 and the lowermost first interlayer dielectric layer ILDa. The source structure SC may correspond to the common source line CSL of FIG. 1 or the common source line 3205 of FIG. 3 or 4. The source structure SC may extend in the first and second directions D1 and D2 in parallel to the first and second gate electrodes ELa and ELb. The source structure SC may include a first source conductive pattern SCP1 and a second source conductive pattern SCP2 that are sequentially stacked. The second source conductive pattern SCP2 may be provided between the first source conductive pattern SCP1 and the lowermost first interlayer dielectric layer ILDa. The first source conductive pattern SCP1 may have a thickness greater than that of the second source conductive pattern SCP2. Each of the first and second source conductive patterns SCP1 and SCP2 may include an impurity-doped semiconductor material. For example, the first source conductive pattern SCP1 may have an impurity concentration greater than that of the second source conductive pattern SCP2.

On the cell array region CAR, a plurality of first vertical channel structures VS1 may be provided to penetrate the stack structure ST and the source structure SC. The first vertical channel structures VS1 may penetrate at least a portion of the second substrate 100, and each of the first vertical channel structures VS1 may have a bottom surface at a lower level than that of a top surface of the second substrate 100 and that of a bottom surface of the source structure SC.

When viewed in plan as shown in FIG. 5A, the first vertical channel structures VS1 may be arranged in a zigzag formation along the first direction D1 or the second direction D2. The first vertical channel structures VS1 may not be provided on the contact region CCR. The first vertical channel structures VS1 may correspond to the vertical channel structures 3220 of FIGS. 2 to 4. The first vertical channel structures VS1 may correspond to channels of the first transistors LT1 and LT2, channels of the memory cell transistors MCT, and channels of the second transistors UT1 and UT2 of FIG. 1.

The first vertical channel structures VS1 may be provided in vertical channel holes CH that penetrate the stack structure ST. Each of the vertical channel holes CH may include a first vertical channel hole CHa that penetrates the first stack structure ST1 and a second vertical channel hole CHb that penetrates the second stack structure ST2. The first and second vertical channel holes CHa and CHb of each vertical channel hole CH may be connected to each other in the third direction D3.

Each of the first vertical channel structures VS1 may include a first part VS1a and a second part VS1b. The first part VS1a may be provided in the first vertical channel hole CHa, and the second part VS1b may be provided in the second vertical channel hole CHb. The second part VS1b may be provided on and connected to the first part VS1a.

For example, each of the first and second parts VS1a and VS1b may have a width in the first direction D1 or the second direction D2 that decreases in the third direction D3. A width at an uppermost segment of the first part VS1a may be greater than a width at a lowermost segment of the second part VS1b. For example, each of the first vertical channel structures VS1 may have a sidewall that has a step difference at a boundary between the first part VSla and the second part VS1b. This, however, is merely an example, and the present inventive concepts are not limited thereto. For example, each of the first vertical channel structures VS1 may have a sidewall that has three or more step differences at different levels or that is flat with no step difference.

Each of the first vertical channel structures VS1 may include a data storage pattern DSP that is adjacent to the stack structure ST (or that is on and at least partially covers an inner wall of the vertical channel hole CH), a vertical semiconductor pattern VSP that is conformally formed on and at least partially covers an inner wall of the data storage pattern DSP, a buried dielectric pattern VI that at least partially fills an internal space bordered or surrounded by the vertical semiconductor pattern VSP, and a conductive pad PAD that is provided in a space bordered or surrounded by the buried dielectric pattern VI and the data storage pattern DSP (or bordered or surrounded by the vertical semiconductor pattern VSP). A top surface of each of the first vertical channel structures VS1 may have, for example, a circular shape, an oval shape, or a bar shape.

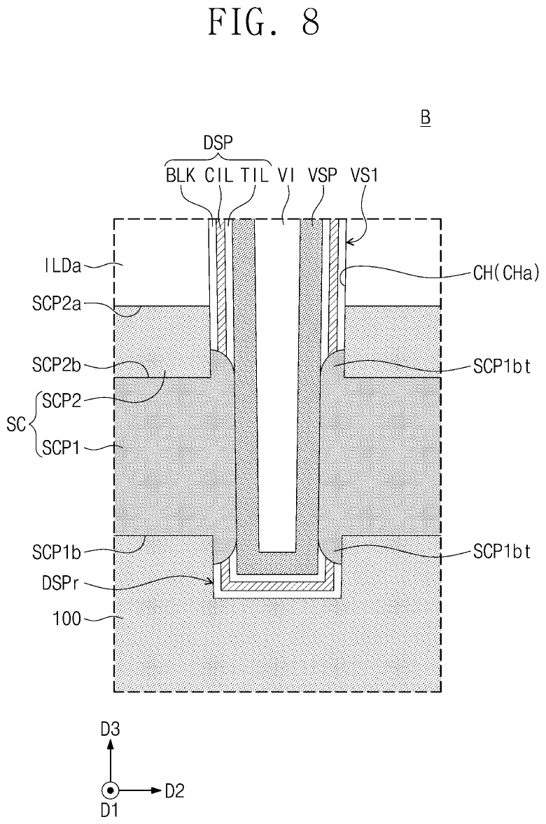

The vertical semiconductor pattern VSP may be provided between the data storage pattern DSP and the buried dielectric pattern VI. The vertical semiconductor pattern VSP may have a macaroni shape or a pipe shape whose bottom end is closed. The data storage pattern DSP may have a macaroni shape or a pipe shape whose bottom end is opened. The vertical semiconductor pattern VSP may include, for example, an impurity-doped semiconductor material, an impurity-undoped intrinsic semiconductor material, or a polycrystalline semiconductor material. As described below with reference to FIG. 8, the vertical semiconductor pattern VSP may be in physical contact with a portion of the source structure SC. The conductive pad PAD may include, for example, an impurity-doped semiconductor material or a conductive material.

The contact region CCR may be provided thereon with a plurality of second vertical channel structures VS2 that penetrate the source structure SC, the stack structure ST, and a planarized dielectric layer 130, which will be described below. For example, the second vertical channel structures VS2 may penetrate the pad portions ELp of the first and second gate electrodes ELa and ELb. The second vertical channel structures VS2 may be provided around cell contact plugs CCP, which will be described below. The second vertical channel structures VS2 may not be provided on the cell array region CAR. The second vertical channel structures VS2 may be formed simultaneously with the first vertical channel structures VS1 and may have substantially the same configuration as that of the first vertical channel structures VS1. However, the second vertical channel structures VS2 may not be provided in accordance with some embodiments.

The contact region CCR may be provided thereon with a planarized dielectric layer 130 that at least partially covers the stack structure ST and the second substrate 100. For example, the planarized dielectric layer 130 may at least partially cover the stepwise structure of the stack structure ST and may be provided on the pad portions ELp of the first and second gate electrodes ELa and ELb. The planarized dielectric layer 130 may have a substantially flat top surface. The top surface of the planarized dielectric layer 130 may be substantially coplanar with an uppermost surface of the stack structure ST. For example, the top surface of the planarized dielectric layer 130 may be substantially coplanar with that of the uppermost second interlayer dielectric layer ILDb included in the stack structure ST.

The planarized dielectric layer 130 may include a single dielectric layer or a plurality of stacked dielectric layers. The planarized dielectric layer 130 may include a dielectric material, such as one or more of silicon oxide, silicon nitride, silicon oxynitride, and low-k dielectric materials. The planarized dielectric layer 130 may include a different dielectric material from that of the first and second interlayer dielectric layers ILDa and ILDb included in the stack structure ST. For example, when the first and second interlayer dielectric layers ILDa and ILDb of the stack structure ST include high-density plasma oxide, the planarized dielectric layer 130 may include tetraethylorthosilicate (TEOS).

An upper dielectric layer 150 may be provided on the planarized dielectric layer 130 and the stack structure ST. The upper dielectric layer 150 may at least partially cover the top surface of the planarized dielectric layer 130, the top surface of the uppermost second interlayer dielectric layer ILDb included in the stack structure ST, and the top surfaces of the first and second vertical channel structures VS1 and VS2.

The upper dielectric layer 150 may include a single dielectric layer or a plurality of stacked dielectric layers. The upper dielectric layer 150 may include, for example, silicon oxide, silicon nitride, silicon oxynitride, or low-k dielectric materials. The upper dielectric layer 150 may include, for example, a dielectric material that is substantially the same as that of the planarized dielectric layer 130 and is different from that of the first and second interlayer dielectric layers ILDa and ILDb included in the stack structure ST.

Bit-line contact plugs BLCP may be provided to penetrate the upper dielectric layer 150 and to have a connection with the first vertical channel structures VS1. The bit-line contact plugs BLCP may be spaced apart from each other.

Cell contact plugs CCP may be provided to penetrate the upper dielectric layer 150 and the planarized dielectric layer 130 and to have a connection with the first and second gate electrodes ELa and ELb. Each of the cell contact plugs CCP may penetrate one of the first and second interlayer dielectric layers ILDa and ILDb to come into physical contact with one of the pad portions ELp of the first and second gate electrodes ELa and ELb. The cell contact plugs CCP may be adjacent to a plurality of second vertical channel structures VS2 and may be spaced apart from each other. The cell contact plugs CCP may correspond to the gate connection lines 3235 of FIG. 4.

A peripheral contact plug TCP may be provided to penetrate the upper dielectric layer 150, the planarized dielectric layer 130, and at least a portion of the peripheral circuit dielectric layer 30 and to have an electrical connection with the peripheral transistors PTR of the peripheral circuit structure PS. Differently from that shown, the peripheral contact plug TCP may be provided in plural. The peripheral contact plug TCP may be spaced apart in the first direction D1 from the second substrate 100, the source structure SC, and the stack structure ST. The peripheral contact plug TCP may correspond to the through line 3245 of FIG. 3 or 4.

For example, the bit-line contact plugs BLCP, the cell contact plugs CCP, and the peripheral contact plug TCP may each have a width in the first direction D1 or the second direction D2 that decreases in the third direction D3.

The upper dielectric layer 150 may be provided thereon with bit lines BL connected to corresponding bit-line contact plugs BLCP. The bit line BL may correspond to the bit line BL of FIG. 1 and/or the bit line 3240 of FIG. 3 or 4.

The upper dielectric layer 150 may be provided thereon with first conductive lines CL1 connected to the cell contact plugs CCP and also with a second conductive line CL2 connected to the peripheral contact plug TCP. The first and second conductive lines CL1 and CL2 may correspond to the conductive lines 3250 of FIG. 4.

The bit-line contact plugs BLCP, the cell contact plugs CCP, the peripheral contact plug TCP, the bit lines BL, and the first and second conductive lines CL1 and CL2 may include a conductive material, such as metal. Although not shown, the upper dielectric layer 150 may further be provided thereon with additional lines and additional vias that are electrically connected to the bit lines BL and the first and second conductive lines CL1 and CL2.

When the stack structure ST is provided in plural, a separation structure SP may be provided to extend in the first direction D1 across between the plurality of stack structures ST. The separation structure SP may correspond to the separation structure 3230 of FIG. 3 or 4. The separation structure SP may be spaced apart in the second direction D2 from the first and second vertical channel structures VS1 and VS2. The separation structure SP may include a dielectric material, such as one or more of silicon oxide, silicon nitride, and silicon oxynitride. The separation structure SP may have, for example, a single unitary structure including one dielectric material. The separation structure SP may include the same dielectric material as that of the first and second interlayer dielectric layers ILDa and ILDb, but the present inventive concepts are not limited thereto.

The separation structure SP may be provided in plural, and the plurality of separation structures SP may be spaced apart from each other in the second direction D2 across the stack structure ST. For convenience, the following will describe a single separation structure SP, but the following description may also be applicable to other separation structures SP.

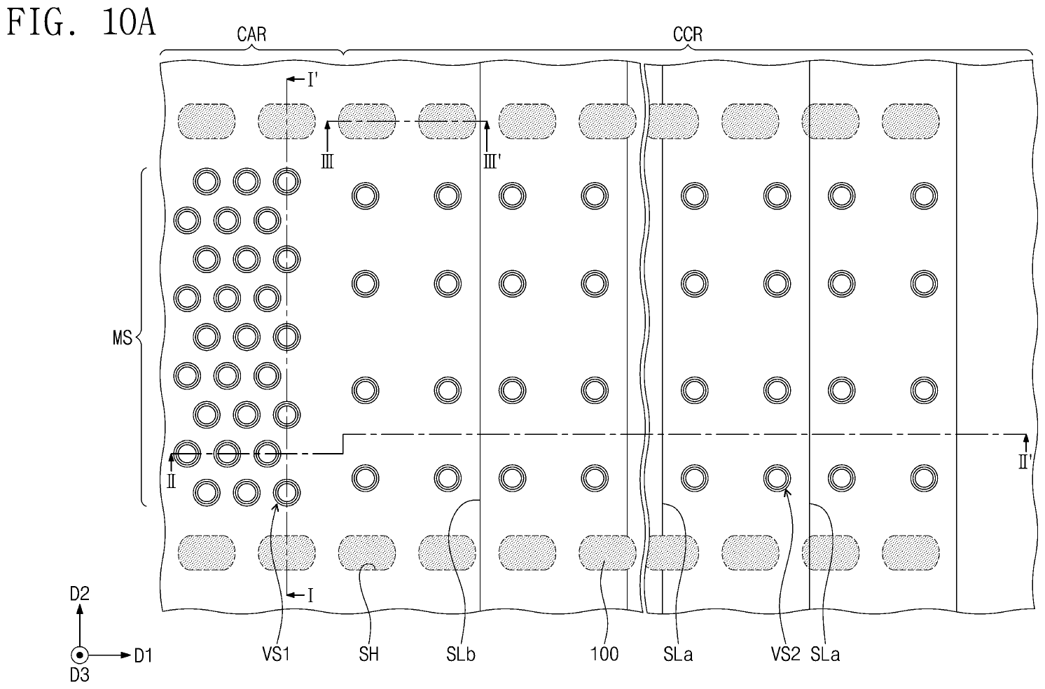

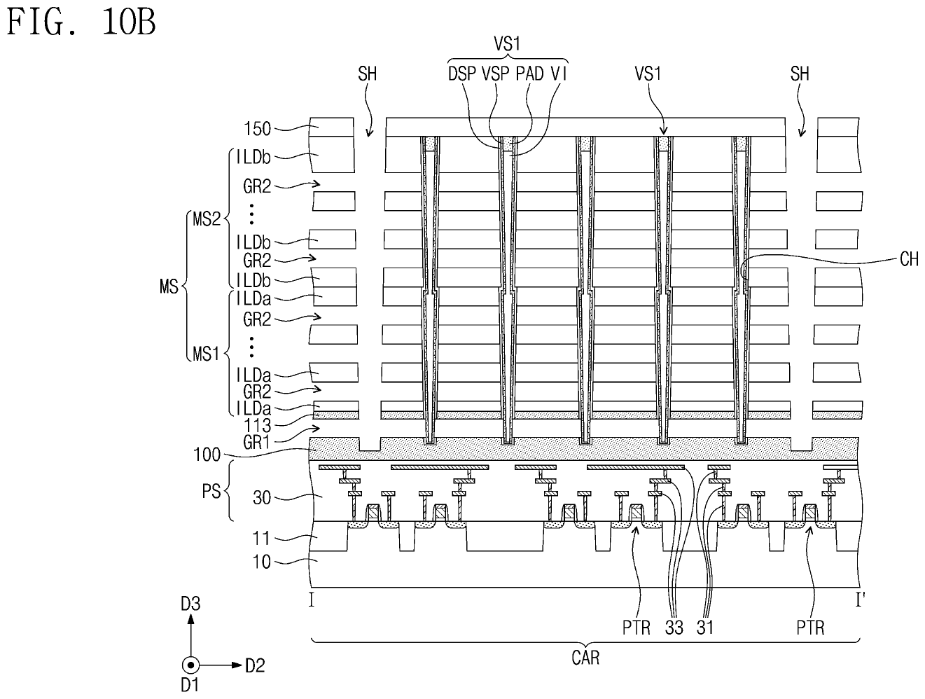

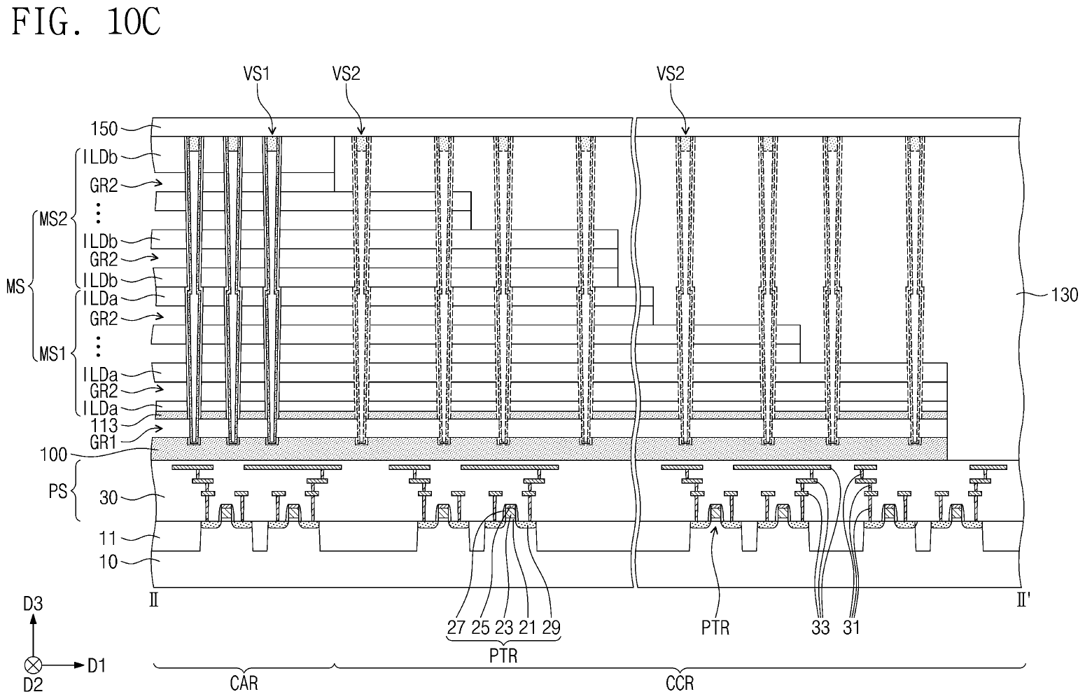

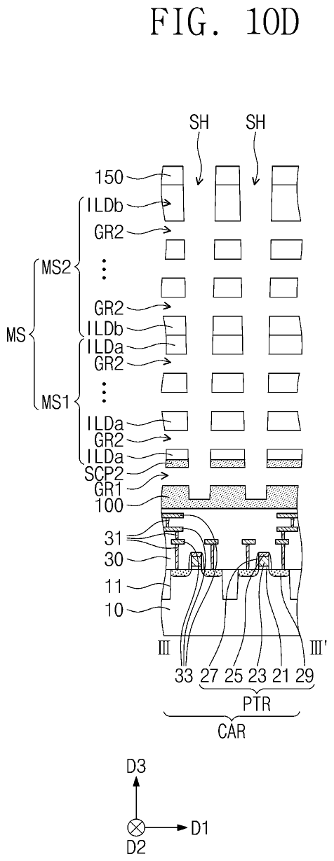

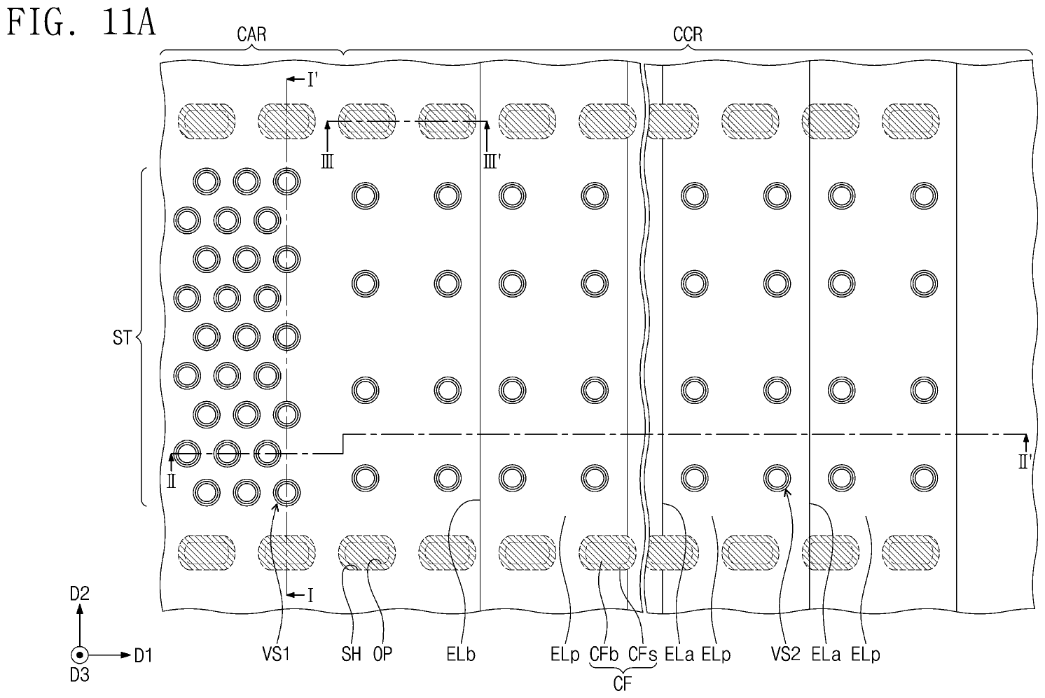

The separation structure SP may fill a separation holes SH, which will be discussed below with reference to FIGS. 10A to 10D, and may include first parts SPa each having a pillar shape that extend in the third direction D3, and may also include second parts SPb that border or surround the first parts SPa when viewed in plan and connect the first parts SPa to each other.

Each of the first parts SPa may have a width in the first direction D1 or the second direction D2 that deceases in the third direction D3. For example, each of the first parts SPa may have an upper width greater than a lower width. The first parts SPa may have their sidewalls SPas in physical contact with the first and second interlayer dielectric layers ILDa and ILDb, and may physically contact the second parts SPb between the first and second interlayer dielectric layers ILDa and ILDb. The first parts SPa may be spaced apart from each other in the first direction D1.

Each of the second parts SPb may be spaced apart in a horizontal direction from the sidewall SPas of each of the first parts SPa. In this description below, the expression “horizontal direction” may indicate a direction parallel to the first and second directions D1 and D2. Each of the second parts SPb may be positioned between the first and second interlayer dielectric layers ILDa and ILDb or between the second source conductive pattern SCP2 and the second substrate 100. Each of the second parts SPb may be located at a level the same as that of the first and second gate electrodes ELa and ELb or that of the first source conductive pattern SCP1. For example, each of the second parts SPb may have top and bottom surfaces substantially coplanar with those of the first and second gate electrodes ELa and ELb or those of the first source conductive pattern SCP1. Each of the second parts SPb may have a width substantially the same as that of the first and second gate electrodes ELa and ELb or that of the first source conductive pattern SCP1. The second parts SPb may be spaced apart from each other in the third direction D3. An uppermost one of the second parts SPb may have a top surface at a level lower than that of the top surfaces of the first and second vertical channel structures VS1 and VS2 and that of top surfaces of the first parts SPa.

The second parts SPb may each have a sidewall SPbs in physical contact with the first gate electrode ELa, the second gate electrode ELb, or the first source conductive pattern SCP1, each of which ELa, ELb, and SCP1 is adjacent in the second direction D2 to the second part SPb. In addition, the sidewalls SPbs of the second parts SPb extending from the sidewall SPas of one of the first parts SPa adjacent to each other in the first direction D1 may be in physical contact with and connected to the second parts SPb extending from the sidewall SPas of another of the first parts SPa adjacent to each other in the first direction D1.

When viewed in cross-section as shown in FIG. 5B, the second parts SPb that extend in the second direction D2 from the sidewall SPas of each of the first parts SPa may have their lengths that are substantially the same as each other. When viewed in cross-section as shown in FIG. 5D, the first parts SPa adjacent to each other in the first direction D1 may be unitarily or monolithically connected to the second parts SPb through the first and second interlayer dielectric layers ILDa and ILDb. The first parts SPa adjacent to each other in the first direction D1 may not have therebetween a conductive material that corresponds to the first and second gate electrodes ELa and ELb. As the first parts SPa are unitarily or monolithically connected to the second parts SPb through the first and second interlayer dielectric layers ILDa and ILDb, when viewed in plan as shown in FIG. 5A, the separation structure SP may extend in the first direction D1 and separate a plurality of stack structures ST from each other.

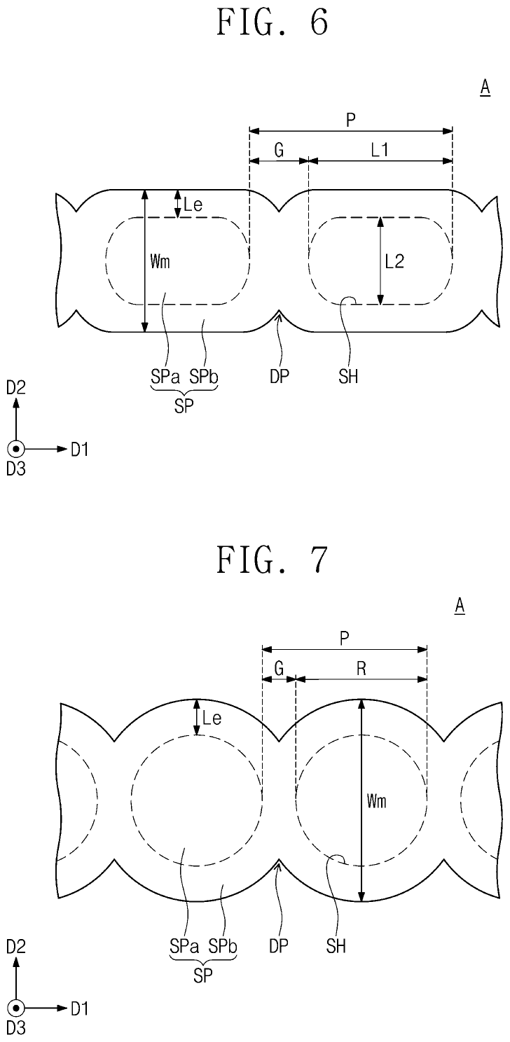

FIGS. 6 and 7 are enlarged cross-sectional views of section A depicted in FIG. 5A, partially illustrating a three-dimensional semiconductor memory device according to some embodiments of the present inventive concepts.

FIGS. 6 and 7 show a top surface shape of the separation structure SP that is visible in a plan view obtained by cutting one of the first and second gate electrodes ELa and ELb in a parallel direction (or horizontal direction) to the top surface of the second substrate 100.

Referring to FIGS. 5B, 5D, and 6, the top surface of each first part SPa included in the separation structure SP may have, for example, an oval shape, a rectangular shape whose four corners are rounded, or a stadium shape in which semicircles are combined with opposite sides of a rectangular shape. For example, the top surface of each first part SPa may have an oval shape having a major axis with a first length L1 and a minor axis with a second length L2. The first length L1 may be a maximum length in the first direction D1 at the top surface of each first part SPa, and the second length L2 may be a maximum length in the second direction D2 at the top surface of each first part SPa. The first length L1 and the second length L2 may each range, for example, from about 90 nm to about 130 nm. For example, the first length L1 may be greater than the second length L2.

The first parts SPa may be spaced apart from each other in the first direction D1, and an interval G in the first direction D1 between the first parts SPa may range, for example, from about 30 nm to about 70 nm. The interval G in the first direction D1 between the first parts SPa may be defined to refer to a minimum distance in a horizontal direction between the sidewalls SPas of the first parts SPa adjacent to each other in the first direction D1. The interval G in the first direction D1 between the first parts SPa may decrease with increasing distance in the third direction D3 from a bottom surface of each of the first parts SPa.

A pitch P of the first parts SPa may range, for example, from about 120 nm to about 200 nm. The pitch P of the first parts SPa may be the same as a sum of the first length L1 and the interval G. The pitch P of the first parts SPa may be, for example, substantially the same as a pitch in the first direction D1 of the first vertical channel structures VS1 or a pitch in the first direction D1 of the second vertical channel structures VS2.

The second parts SPb extending from the sidewall SPas of the first part SPa may have an extending length Le in a horizontal direction that ranges, for example, from about 20 nm to about 50 nm. The extending length Le of the second part SPb may be, for example, equal to or greater than about 30 nm. The extending length Le of the second part SPb may be less than a distance between the sidewall SPbs of the second part SPb and a closer one of the first and second vertical channel structures VS1 and VS2. The extending length Le of the second part SPb may be equal to or greater than half the interval G in the first direction D1 between the first parts SPa.

The top surface in the second direction D2 of the separation structure SP including the first parts SPa and the second parts SPb may have a maximum width Wm in the second direction D2 that ranges, for example, from about 110 nm to about 210 nm. The maximum width Wm in the second direction D2 at the top surface of the separation structure SP may be the same as a sum of the second length L2 and the extending length Le.

The separation structure SP may have a depression DP where a width in the second direction D2 is generally minimal. The depression DP of the separation structure SP may be positioned between the first parts SPa. The sidewall SPbs of each of the second parts SPb included in the separation structure SP may have a profile shaped like an embossed line that extends in the first direction D1.

Referring to FIGS. 5B, 5D, and 7, each of the first parts SPa included in the separation structure SP may have, for example, a circular shape at the top surface thereof. For example, the top surface of each first part SPa may have a circular shape whose diameter R is constant. The diameter R of the top surface of each first part SPa may be, for example, substantially the same as a diameter of the top surface of the first and second vertical channel structures VS1 and VS2. However, the description with reference to FIGS. 6 and 7 is merely an example, and the present inventive concepts are not limited thereto, and each of the first parts SPa may have various shapes at the top surface thereof.

FIG. 8 illustrates an enlarged view of section B depicted in FIG. 5B, partially showing a three-dimensional semiconductor memory device according to some embodiments of the present inventive concepts.

FIGS. 5B and 8 show the source structure SC including the first and second source conductive patterns SCP1 and SCP2 and also show one of the first vertical channel structures VS1 each including the data storage pattern DSP, the vertical semiconductor pattern VSP, the buried dielectric pattern VI, and a lower data storage pattern DSPr. For convenience of description, the following will describe a single stack structure ST and a single first vertical channel structure VS1, and the following description may also be applicable to other first vertical channel structures VS1 that penetrate other stack structures ST.

The data storage pattern DSP may include a blocking dielectric layer BLK, a charge storage layer CIL, and a tunneling dielectric layer TIL that are sequentially stacked. The blocking dielectric layer BLK may be adjacent to the stack structure ST or the source structure SC, and the tunneling dielectric layer TIL may be adjacent to the vertical semiconductor pattern VSP. The charge storage layer CIL may be interposed between the blocking dielectric layer BLK and the tunneling dielectric layer TIL. The blocking dielectric layer BLK may be on and at least partially cover an inner wall of the vertical channel hole CH (or inner wall of the first vertical channel hole CHa)).

The blocking dielectric layer BLK, the charge storage layer CIL, and the tunneling dielectric layer TIL may extend in the third direction D3 between the stack structure ST and the vertical semiconductor pattern VSP. The data storage pattern DSP may store and/or change data by using Fowler-Nordheim tunneling induced by a voltage difference between the vertical semiconductor pattern VSP and the first and second gate electrodes ELa and ELb. For example, the blocking dielectric layer BLK and the tunneling dielectric layer TIL may include silicon oxide, and the charge storage layer CIL may include silicon nitride or silicon oxynitride.

The first source conductive pattern SCP1 of the source structure SC may be in physical contact with the vertical semiconductor pattern VSP, and the second source conductive pattern SCP2 of the source structure SC may be spaced apart from the vertical semiconductor pattern VSP across the data storage pattern DSP. The first source conductive pattern SCP1 may be spaced apart from the buried dielectric pattern VI across the vertical semiconductor pattern VSP.

For example, the first source conductive pattern SCP1 may include protrusions SCP1bt located at a level higher than that of a bottom surface SCP2b of the second source conductive pattern SCP2 or lower than that of a bottom surface SCP1b of the first source conductive pattern SCP1. The protrusions SCP1bt may be located at a level lower than that of a top surface SCP2a of the second source conductive pattern SCP2. The protrusions SCP1bt may each have, for example, a curved shape at a surface in physical contact with the data storage pattern DSP or the lower data storage pattern DSPr.

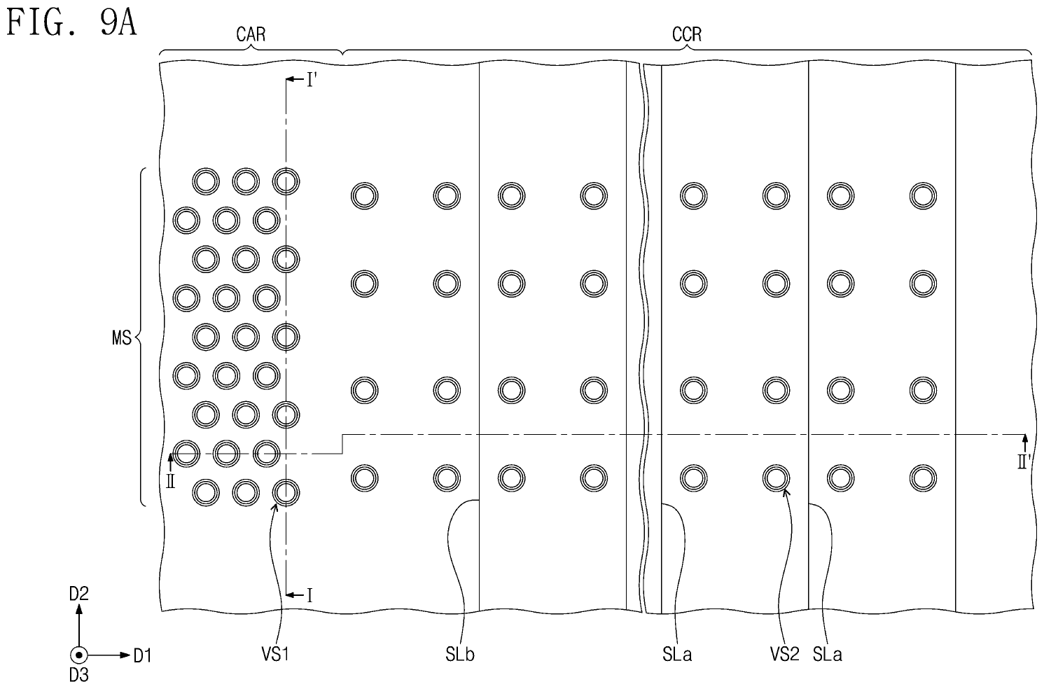

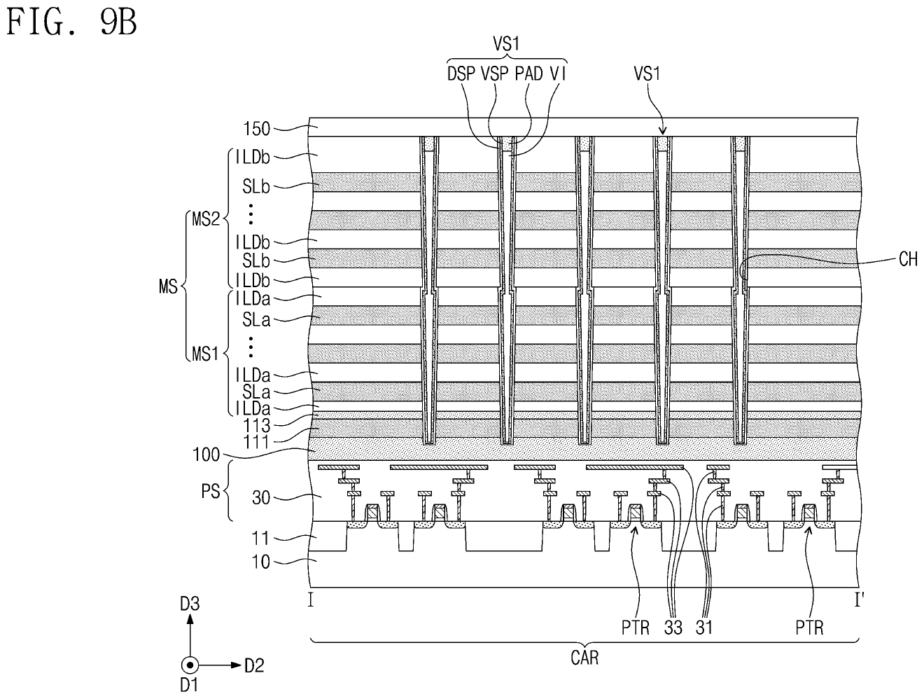

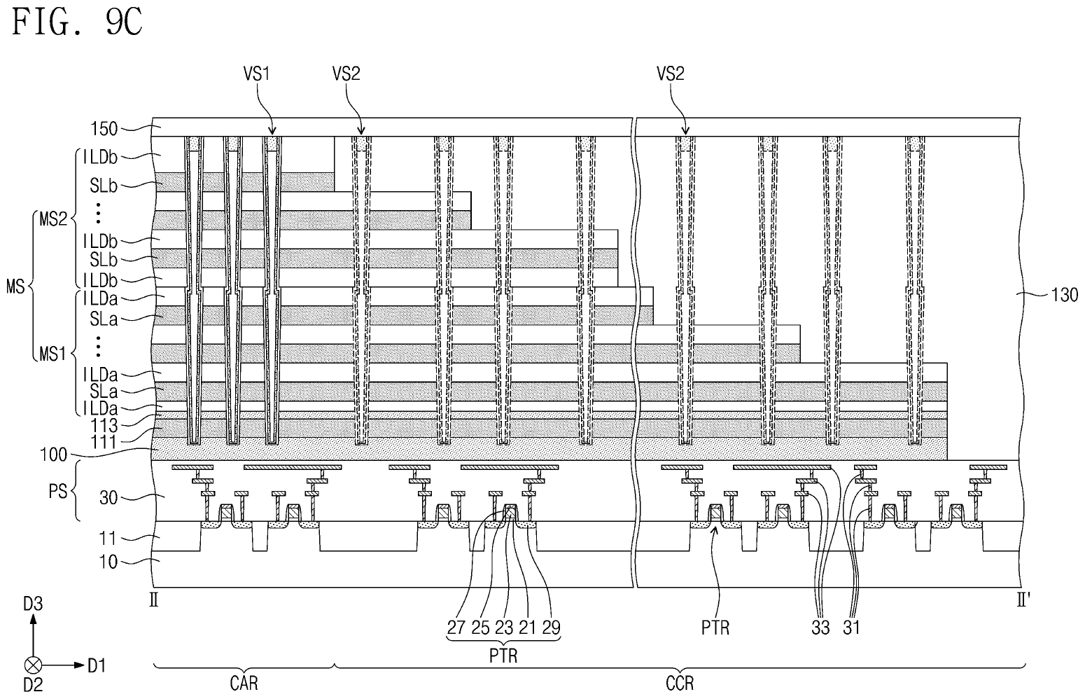

FIGS. 9A, 10A, 11A, and 12A are plan views illustrating a method of fabricating a three-dimensional semiconductor memory device according to some embodiments of the present inventive concepts. FIGS. 9B, 9C, 10B to 10D, 11B to 11D, 12B, and 12C are cross-sectional views taken along lines I-I′, II-II′, and III-III′ of FIGS. 9A, 10A, 11A, and 12A, illustrating a method of fabricating a three-dimensional semiconductor memory device according to some embodiments of the present inventive concepts. The following will describe in detail a method of fabricating a three-dimensional semiconductor memory device according to some embodiments of the present inventive concepts with reference to FIGS. 9A to 9C, 10A to 10D, 11A to 11D, 12A to 12C, and 5A to 5D.

Referring to FIGS. 9A, 9B, and 9C, a first substrate 10 may be provided to include a cell array region CAR and a contact region CCR. A device isolation layer 11 may be formed to define active areas in the first substrate 10. The device isolation layer 11 may be formed by forming a trench on an upper portion of the first substrate 10 and at least partially filling the trench with silicon oxide.

Peripheral transistors PTR may be formed on the active areas defined by the device isolation layer 11. Peripheral circuit plugs 31 and peripheral circuit lines 33 may be formed to have a connection with peripheral source/drain sections 29 of the peripheral transistors PTR. A peripheral circuit dielectric layer 30 may be formed to at least partially cover the peripheral transistors PTR, the peripheral circuit plugs 31, and the peripheral circuit lines 33.

A second substrate 100 may be formed on the peripheral circuit dielectric layer 30. The second substrate 100 may extend from the cell array region CAR toward the contact region CCR.

The second substrate 100 may be partially removed on the contact region CCR. The partial removal of the second substrate 100 may include forming a mask pattern that at least partially covers the cell array region CAR and a portion of the contact region CCR, and then using the mask pattern to pattern the second substrate 100. The partial removal of the second substrate 100 may include forming a space where a peripheral contact plug TCP will be provided as described below.

A lower sacrificial layer 111 and a lower semiconductor layer 113 may be formed on the second substrate 100. A mold structure MS may be formed on the lower semiconductor layer 113. The formation of the mold structure MS may include forming a first mold structure MS1 by alternately and repeatedly stacking first interlayer dielectric layers ILDa and first sacrificial layers SLa on the second substrate 100, and forming a second mold structure MS2 by alternately and repeatedly stacking second interlayer dielectric layers ILDb and second sacrificial layers SLb on the first mold structure MS1.

The first and second sacrificial layers SLa and SLb may be formed of a dielectric material different from that of the first and second interlayer dielectric layers ILDa and ILDb. The first and second sacrificial layers SLa and SLb may be formed of a material having an etch selectivity with respect to the first and second interlayer dielectric layers ILDa and ILDb. For example, the first and second sacrificial layers SLa and SLb may be formed of silicon nitride, and the first and second interlayer dielectric layers ILDa and ILDb may be formed of silicon oxide. The first and second sacrificial layers SLa and SLb may be formed to have substantially the same thickness, and the first and second interlayer dielectric layers ILDa and ILDb may be formed to have their thicknesses that are changed at certain portions thereof.

A trimming process may be performed on the mold structure MS on the contact region CCR. The trimming process may include forming a mask pattern that at least partially covers a top surface of the mold structure MS on the cell array region CAR and the contact region CCR, using the mask pattern to pattern the mold structure MS, reducing an area of the mask pattern, and using the reduced mask pattern to pattern the mold structure MS. The reduction in area of the mask pattern and the patterning the mold structure MS by using the mask pattern may be performed alternately and repeatedly. The trimming process may cause the mold structure MS to have a stepwise structure.

A planarized dielectric layer 130 may be formed to at least partially cover the stepwise structure of the mold structure MS on the contact region CCR and a portion of a top surface of the peripheral circuit dielectric layer 30. The formation of the planarized dielectric layer 130 may include allowing a dielectric material to at least partially cover the stepwise structure of the mold structure MS and a portion of the top surface of the peripheral circuit dielectric layer 30, and performing a planarization process until the top surface of the mold structure MS is exposed. The planarized dielectric layer 130 may have a top surface substantially coplanar with that of the mold structure MS. In the description below, the phrase “substantially coplanar with” may mean that a planarization process can be performed. The planarization process may include, for example, a chemical mechanical polishing (CMP) process or an etch-back process.

Vertical channel holes CH may be formed to penetrate the mold structure MS, and first and second vertical channel structures VS1 and VS2 may be formed to at least partially fill the vertical channel holes CH. On the cell array region CAR, the vertical channel holes CH may penetrate the mold structure MS, the lower semiconductor layer 113, and the lower sacrificial layer 111. On the contact region CCR, the vertical channel holes CH may penetrate the planarized dielectric layer 130, the mold structure MS, the lower semiconductor layer 113, and the lower sacrificial layer 111. The vertical channel holes CH may penetrate at least a portion of the second substrate 100, and may each have a bottom surface at a level lower than that of a top surface of the second substrate 100.

The formation of the first and second vertical channel structures VS1 and VS2 may include forming a data storage pattern DSP that is on and at least partially conformally covers an inner wall of the vertical channel hole CH, forming a vertical semiconductor pattern VSP that is on and at least partially conformally covers an inner wall of the data storage pattern DSP, forming a buried dielectric pattern VI that fills at least a portion of a space surrounded by the vertical semiconductor pattern VSP, and forming a conductive pad PAD that at least partially fills a space bordered or surrounded by the buried dielectric pattern VI.

An upper dielectric layer 150 may be formed to cover the mold structure MS and the planarized dielectric layer 130. The upper dielectric layer 150 may cover top surfaces of the first and second vertical channel structures VS1 and VS2.

Referring to FIGS. 10A to 10D, a plurality of separation holes SH may be formed to penetrate the mold structure MS, the lower semiconductor layer 113, and the lower sacrificial layer 111. The separation holes SH may penetrate at least a portion of the second substrate 100, and may each have a bottom surface at a level lower than that of the top surface of the second substrate 100. The bottom surface of each of the separation holes SH may be located at a level lower than that of the bottom surface of each of the vertical channel holes CH, but the present inventive concepts are not limited thereto. The separation holes SH may be arranged and spaced apart from each other in a first direction D1. The separation holes SH may externally expose a portion of the top surface of the second substrate 100.

After the formation of the separation holes SH, a portion of the mold structure MS may remain between the separation holes SH that are spaced apart from each other in the first direction D1. Therefore, even without a process of forming a separate support structure, a collapse of the mold structure MS may be prevented or reduced in likelihood.

Referring to FIGS. 9B and 9C with FIGS. 10B and 10C, the sacrificial layers 111, SLa, and SLb exposed to the separation holes SH may be selectively removed. The selective removal of the sacrificial layers 111, SLa, and SLb may be achieved by , for example, a wet etching process that uses an etching solution.

The selective removal of the sacrificial layers 111, SLa, and SLb may form a first gap region GR1 defined as a space from which the lower sacrificial layer 111 is removed, and may also form second gap regions GR2 defined as spaces from which the first and second sacrificial layers SLa and SLb are removed.

The first gap region GR1 may extend to a sidewall of the vertical semiconductor pattern VSP of each of the first and second vertical channel structures VS1 and VS2. For example, during or after the removal of the lower sacrificial layer 111, the data storage pattern DSP may be partially removed from each of the first and second vertical channel structures VS1 and VS2, and the sidewall of the vertical semiconductor pattern VSP may be exposed. The second gap regions GR2 may connect a plurality of separation holes SH to each other.

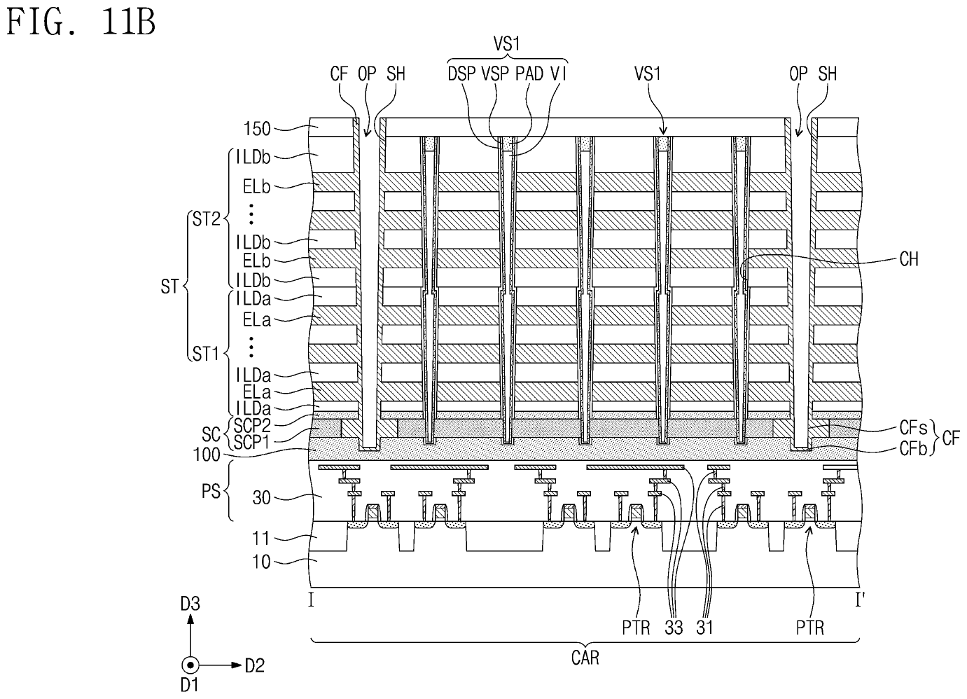

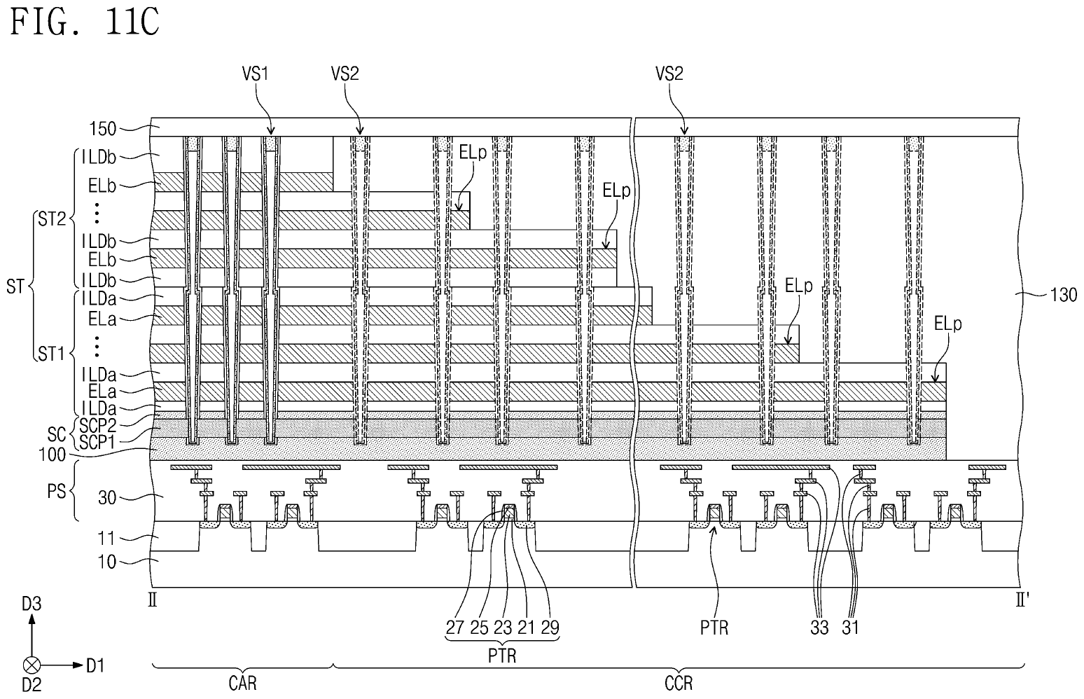

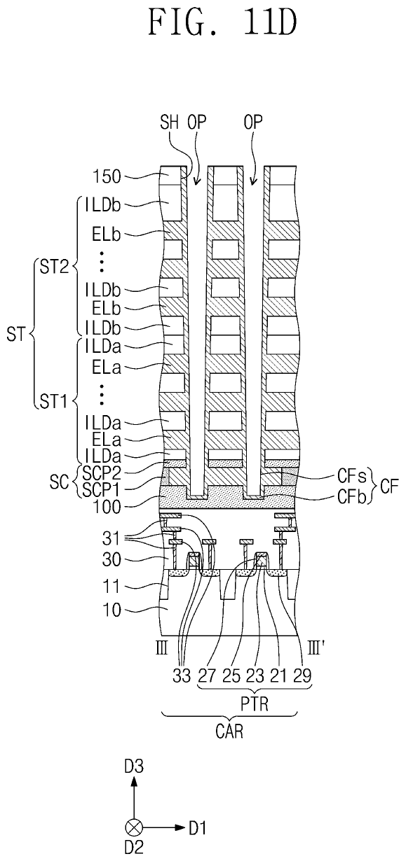

Referring to FIGS. 10A to 10D and 11A to 11D, a first source conductive pattern SCP1 may be formed to at least partially fill the first gap region GR1. The first source conductive pattern SCP1 may be formed of, for example, an impurity-doped semiconductor material. Although not shown, an air gap may be formed in the first source conductive pattern SCP1. The lower semiconductor layer 113 may be called a second source conductive pattern SCP2, and as a result, a source structure SC may be formed to include the first and second source conductive patterns SCP1 and SCP2. The selective removal of the first and second sacrificial layers SLa and SLb may be performed after the formation of the source structure SC.

First and second gate electrodes ELa and ELb may be formed to at least partially fill the second gap regions GR2, and a conductive layer CF may be formed to fill at least a portion of each of the separation holes SH. In conclusion, a stack structure ST may be formed to include the first and second gate electrodes ELa and ELb and the first and second interlayer dielectric layers ILDa and ILDb. The conductive layer CF may be on and at least partially conformally cover the bottom surface and an inner wall of each of the separation holes SH, and may be unitarily or monolithically connected to the first and second gate electrodes ELa and ELb. For example, the conductive layer CF may include a first part CFb that at least partially covers the bottom surface of each of the separation holes SH and a second part CFs that at least partially covers an inner wall of each of the separation holes SH. A thickness in a third direction D3 of the first part CFb may be substantially the same as a thickness in a horizontal direction of the second part CFs, and for example may range from about 10 nm to about 40 nm. An opening OP may be defined to indicate an internal space of each of the separation holes SH, which internal space is bordered or surrounded by the first part CFb and the second part CFs of the conductive layer CF. The opening OP may have a width in a horizontal direction that is less than a width in the horizontal direction of each of the separation holes SH.

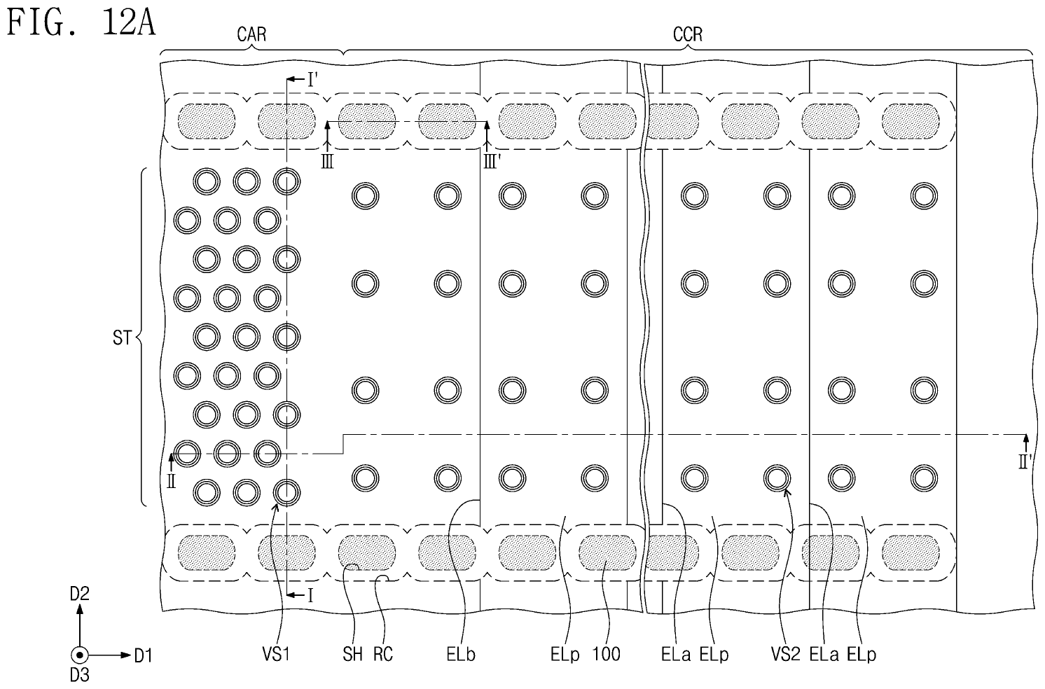

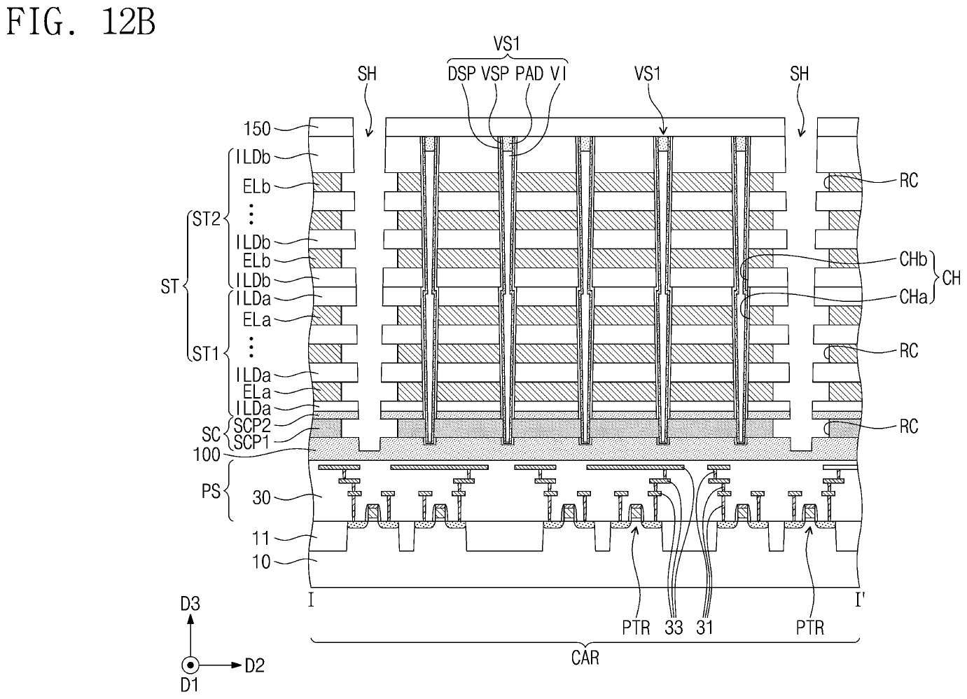

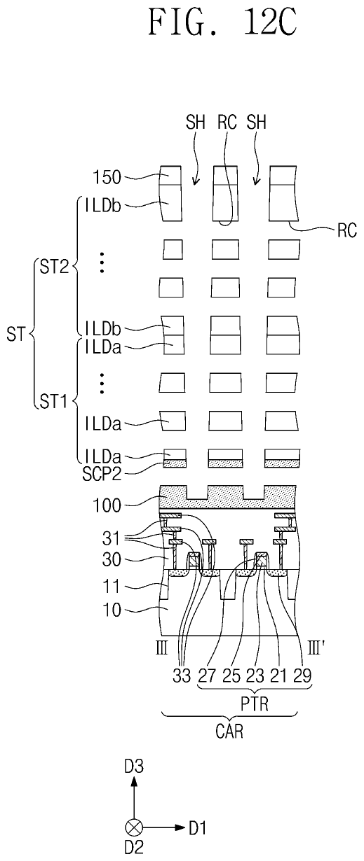

Referring to FIGS. 11A to 11D and 12A to 12C, the conductive layer CF exposed to the opening OP may be removed. In addition, during the removal of the conductive layer CF, a portion of each of the first and second gate electrodes ELa and ELb may be removed together with the conductive layer CF. The removal of the conductive layer CF and the portion of each of the first and second gate electrodes ELa and ELb may be achieved by, for example, a wet etching process that uses an etching solution.

Recessions RC may be defined to indicate spaces where portions of the first and second gate electrodes ELa and ELb are removed. A length in a horizontal direction of each of the recessions RC may range, for example, from about 20 nm to about 50 nm. The length in a horizontal direction of each of the recessions RC may be, for example, equal to or greater than about 30 nm.

When viewed in cross-section as shown in FIG. 12C, the recessions RC extending from one of the separation holes SH adjacent to each other in the first direction D1 may be connected to corresponding recessions RC extending from another of the separation holes SH adjacent to each other in the first direction D1. For example, a plurality of separation holes SH may be connected to each other in the first direction D1 through the recessions RC, and may separate a plurality of stack structures ST from each other.

Referring back to FIGS. 5A, 5B, 5C, and 5D together with FIGS. 12A to 12C, a separation structure SP may be formed to at least partially fill the separation holes SH and the recessions RC. For example, the separation structure SP may include first parts SPa that at least partially fill the separation holes SH and extend in the third direction D3, and may also include second parts SPb that at least partially fill the recessions RC and extend from the first parts SPa.

Bit-line contact plugs BLCP may be formed to penetrate the upper dielectric layer 150, cell contact plugs CCP may be formed to penetrate the upper dielectric layer 150 and the planarized dielectric layer 130 and to have a connection with the first and second gate electrodes ELa and ELb, and a peripheral contact plug TCP may be formed to penetrate the upper dielectric layer 150, the planarized dielectric layer 130, and at least a portion of the peripheral circuit structure PS and to have an electrical connection with the peripheral transistors PTR of the peripheral circuit structure PS.

On the upper dielectric layer 150, bit lines BL may be formed to have a connection with the bit-line contact plugs BLCP, first conductive lines CL1 may be formed to have a connection with the cell contact plugs CCP, and a second conductive line CL2 may be formed to have a connection with the peripheral contact plug TCP. Although not shown, on the upper dielectric layer 150, additional lines and additional vias may further be formed to have an electrical connection with the bit lines BL and the first and second conductive lines CL1 and CL2.

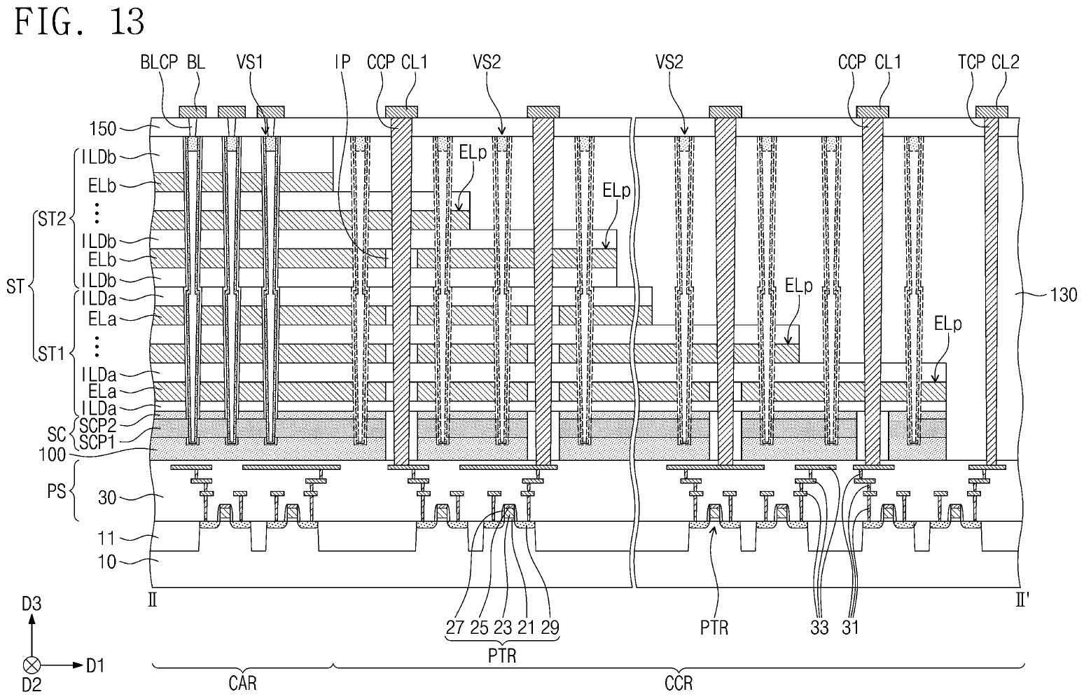

FIG. 13 illustrates a cross-sectional view taken along line II-II′ of FIG. 5A, showing a three-dimensional semiconductor memory device according to some embodiments of the present inventive concepts. For brevity of description, a description of the same features described with reference to FIGS. 5A to 5D will be omitted, and differences therewith will be explained below in detail.

Referring to FIG. 13, each of the cell contact plugs CCP may penetrate the upper dielectric layer 150, the planarized dielectric layer 130, the stack structure ST, the source structure SC, and the second substrate 100 and may have an electrical connection with the peripheral transistors PTR of the peripheral circuit structure PS. The cell contact plugs CCP may have their bottom surfaces at a level lower than that of a bottom surface of the stack structure ST and that of a bottom surface of the source structure SC. Each of the cell contact plugs CCP may be in physical contact with and electrically connected to one of the first and second gate electrodes ELa and ELb. The pad portions ELp of the first and second gate electrodes ELa and ELb may be in contact with corresponding cell contact plugs CCP. Each of the cell contact plugs CCP may be electrically separated and spaced apart in a horizontal direction across dielectric patterns IP from the first and second gate electrodes ELa and ELb below the pad portions ELp, the source structure SC, and the second substrate 100. A length in the third direction D3 of each cell contact plug CCP may be substantially the same as a length in the third direction D3 of the peripheral contact plug TCP.

The formation of the cell contact plugs CCP may include forming vertical holes that penetrate the upper dielectric layer 150, the planarized dielectric layer 130, the stack structure ST, the source structure SC, and the second substrate 100, and then at least partially filling the vertical holes with a conductive material. The vertical holes in which are provided the cell contact plugs CCP and the peripheral contact plug TCP may be formed together with the vertical channel holes CH and the separation holes SH at the same time in the same etching process, and therefore an etching process for a high aspect ratio may be provided that is characterized by reduced difficulty and a fewer number of etching operations.

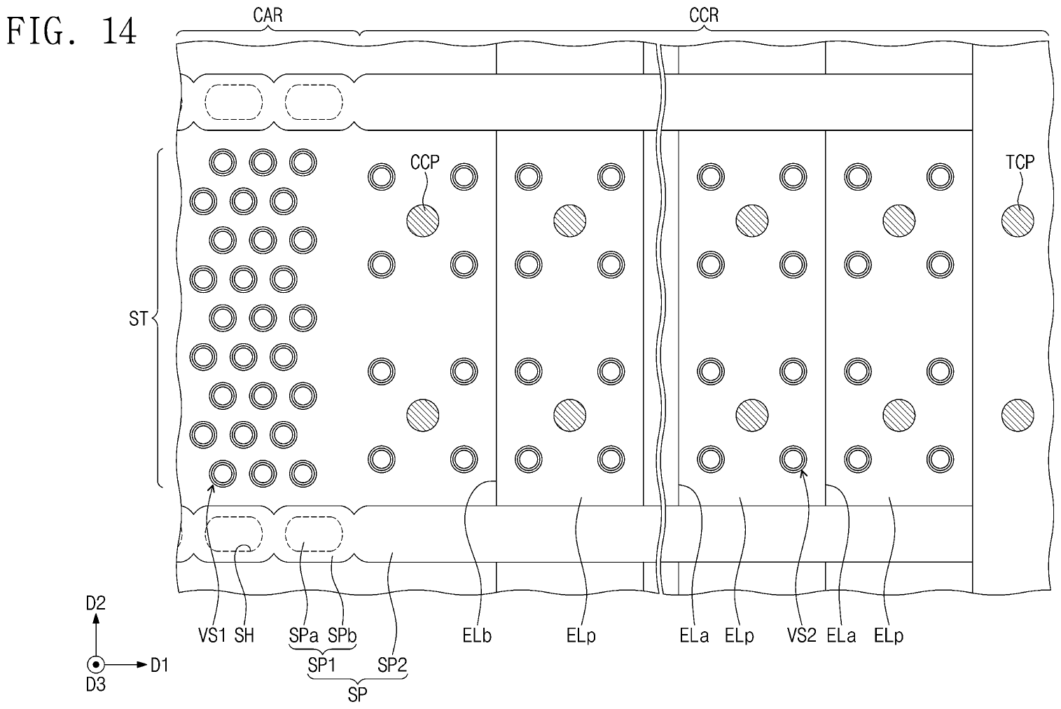

FIG. 14 is a plan view illustrating a three-dimensional semiconductor memory device according to some embodiments of the present inventive concepts. For brevity of description, a description of the same features discussed with reference to FIGS. 5A to 5D will be omitted, and differences therewith will be described below in detail.

Referring to FIG. 14, the separation structure SP may include a first separation structure SP1 on the cell array region CAR and a second separation structure SP2 on the contact region CCR. The first separation structure SP1 on the cell array region CAR may include first parts SPa that at least partially fill the separation holes SH and have pillar shapes extending in the third direction D3, and may also include second parts SPb that border or surround the first parts SPa and connect the first parts SPa to each other when viewed in plan.In contrast, the second separation structure SP2 may have a plate shape that extends in the first direction D1 from the first separation structure SP1. For example, the second separation structure SP2 may have a width in the second direction D2 that is constant in the first direction D1, and may have a sidewall having a line-shape profile parallel to the first direction D1.

According to the present inventive concepts, as vertical channel holes in which vertical channel structures are provided are formed simultaneously with separation holes in which a separation structure is partially provided, an etching process may be used that is less difficult and involves fewer operations. In addition, a portion of a mold structure may remain even after the formation of the separation holes, and thus a collapse of the mold structure may be prevented or the likelihood of happening reduced without forming a separate support structure. Accordingly, a three-dimensional semiconductor memory device may be fabricated using a simplified processes and may have improved reliability and electrical characteristics.

Although the present inventive concepts have been described in connection with the some example embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

What is claimed is:

1. A three-dimensional semiconductor memory device, comprising:
a substrate;
a plurality of stack structures each including a plurality of interlayer dielectric layers and a plurality of gate electrodes, which are alternately and repeatedly stacked on the substrate;
a plurality of vertical channel structures which penetrates the plurality of stack structures; and
a separation structure, which extends in a first direction across between the plurality of stack structures,
wherein the separation structure includes:
a plurality of first parts each having a pillar shape, which extends in a third direction perpendicular to a top surface of the substrate; and
a plurality of second parts, which extends between the plurality of interlayer dielectric layers from sidewalls of the plurality of first parts and which connects ones of the plurality of first parts to each other in the first direction,
wherein the separation structure is spaced apart in a second direction from the plurality of vertical channel structures, the second direction intersecting the first direction.

2. The device of claim 1, wherein a top surface of each of the first parts included in the separation structure has a circular shape, an oval shape, a rectangular shape whose four corners are rounded, or a stadium shape in which semicircles are combined with opposite sides of a rectangular shape.

3. The device of claim 1, wherein the first parts of the separation structure are arranged along the first direction and are spaced apart from each other in the first direction.

4. The device of claim 1, wherein each of the first parts included in the separation structure has a width which increases with increasing distance from the substrate.

5. The device of claim 1, an upper width of each of the first parts included in the separation structure is greater than a lower width of the each of the first parts included in the separation structure.

6. The device of claim 1, wherein a sidewall of each of the second parts included in the separation structure has a profile shaped like an embossed line, which extends in the first direction.

7. The device of claim 1, a sidewall of each of the second parts is in physical contact with ones of the plurality of gate electrodes, which are adjacent in the second direction.

8. The device of claim 1, wherein a length of each of the plurality of second parts extending from a sidewall of the first part is in a range of about 20 nm to about 50 nm.

9. The device of claim 1, wherein the separation structure has a depression between the first parts of the separation structure.

10. The device of claim 1, wherein the substrate includes a cell array region and a contact region, which is adjacent in the first direction to the cell array region,
wherein the device further comprises a plurality of cell contact plugs, which penetrate the stack structure,
wherein bottom surfaces of the plurality of cell contact plugs are at a level lower than a level of bottom surfaces of the plurality of stack structures.

11. The device of claim 1, wherein the substrate includes a cell array region and a contact region, which is adjacent in the first direction to the cell array region,
wherein the separation structure includes a first separation structure on the cell array region and a second separation structure on the contact region,
the first separation structure including
a plurality of first parts each having a pillar shape which extend in the third direction; and
a plurality of second parts, which extends between the plurality of interlayer dielectric layers from sidewalls of the plurality of first parts and which connect the plurality of first parts to each other in the first direction, and
the second separation structure having a plate shape which extends in the first direction from the first separation structure.

12. The device of claim 11, wherein
a width in the second direction of the second separation structure is constant along the first direction, and
a sidewall of the second separation structure has a line-shape profile parallel to the first direction.

13. The device of claim 1, wherein the separation structure is provided in plural,
wherein the plurality of separation structures are spaced apart from each other in the second direction.

14. The device of claim 1, wherein the separation structure includes a dielectric material that is same as a dielectric material of the interlayer dielectric layers included in the stack structures.

15. The device of claim 1, wherein the separation structure has a monolithic structure including one dielectric material.

16. A three-dimensional semiconductor memory device, comprising:
a first substrate including a cell array region and a contact region, which is adjacent in a first direction to the cell array region;
a peripheral circuit structure including a plurality of peripheral transistors on the first substrate;
a second substrate on the peripheral circuit structure, the second substrate extending from the cell array region toward the contact region;
a plurality of stack structures including a plurality of interlayer dielectric layers and a plurality of gate electrodes, which are alternately and repeatedly stacked on the second substrate;
a source structure between the second substrate and the plurality of stack structures;
a planarized dielectric layer on the plurality of stack structures;
a plurality of vertical channel structures, which penetrates the planarized dielectric layer, the plurality of stack structures, and the source structure and which are in physical contact with the second substrate;
an upper dielectric layer on top surfaces of the plurality of stack structures, a top surface of the planarized dielectric layer, and top surfaces of the plurality of vertical channel structures;
a plurality of cell contact plugs on the contact region, the cell contact plugs penetrating the upper dielectric layer and the planarized dielectric layer, the cell contact plugs being in physical contact with the plurality of gate electrodes of the plurality of stack structures; and
a separation structure, which extends in the first direction across the plurality of stack structures,
wherein the separation structure includes:
a plurality of first parts each having a pillar shape, which vertically extends from the second substrate; and
a plurality of second parts, which extends between the plurality of interlayer dielectric layers from sidewalls of the plurality of first parts and which connects ones of the plurality of first parts to each other in the first direction,
wherein a sidewall of each of the second parts has a profile shaped like an embossed line, which extends in the first direction.

17. The device of claim 16, wherein the plurality of vertical channel structures are in a plurality of vertical channel holes, which penetrate the planarized dielectric layer, the plurality of stack structures, the source structure, and at least a portion of the second substrate,
wherein each of the vertical channel structures includes a data storage pattern, which conformally extends on a sidewall of a respective one of the plurality of vertical channel holes and a vertical semiconductor pattern, which is on a sidewall of the data storage pattern.

18. The device of claim 16, wherein the plurality of cell contact plugs penetrate the plurality of stack structures, the source structure, and the second substrate and have electrical connections with the plurality of peripheral transistors of the peripheral circuit structure.

19. An electronic system, comprising:
a three-dimensional semiconductor memory device including:
a substrate,
a plurality of stack structures including a plurality of interlayer dielectric layers and a plurality of gate electrodes, which are alternately and repeatedly stacked on the substrate,
a plurality of vertical channel structures, which penetrates the plurality of stack structures,
a separation structure, which extends in a first direction across the plurality of stack structures,
an upper dielectric layer, which is on top surfaces of the plurality of stack structures and top surfaces of the plurality of vertical channel structures, and
an input/output pad on the upper dielectric layer; and
a controller, which has an electrical connection through the input/output pad with the three-dimensional semiconductor memory device and which is configured to control the three-dimensional semiconductor memory device,
wherein the separation structure includes:
a plurality of first parts each having a pillar shape, which extends in a third direction perpendicular to a top surface of the substrate; and
a plurality of second parts, which extends between the plurality of interlayer dielectric layers from sidewalls of the plurality of first parts and which connects ones of the plurality of first parts to each other in the first direction, and
wherein the separation structure is spaced apart in a second direction from the plurality of vertical channel structures, the second direction intersecting the first direction.

20. The electronic system of claim 19, wherein a sidewall of each of the plurality of second parts included in the separation structure has a profile shaped like an embossed line, which extends in the first direction.
